(19) United States
(12) Patent Application Publication
(10) Pub. No.: US 2026/0215015 A1
(43) Pub. Date: Jul. 23, 2026

(54) IMAGE SENSOR INCLUDING ISOLATION PATTERN AND LINER INCLUDING TWO-DIMENSIONAL MATERIAL

(71) Applicant: Samsung Electronics Co., Ltd., Suwon-si (KR)

(72) Inventor: SANGCHUL SUL, Suwon-si (KR)

(21) Appl. No.: 19/457,472

(22) Filed: Jan. 23, 2026

(30) Foreign Application Priority Data
Jan. 23, 2025 (KR) 10-2025-0010308

(51) Int. Cl. H10F 39/00; H10F 39/18

(52) U.S. Cl. CPC H10F 39/807; H10F 39/182; H10F 39/805; H10F 39/8063; H10F 39/809

(57) ABSTRACT

An image sensor includes a semiconductor substrate including a first surface and a second surface opposite to the first surface, a photodiode element defined in the semiconductor substrate, a PD isolation pattern disposed in an opening penetrating through at least one of the first surface and the second surface of the semiconductor substrate, and a microlens disposed on the second surface. The PD isolation pattern includes an insulating pattern disposed in the opening, an insulating liner disposed between the insulating pattern and the semiconductor substrate, and a conductive liner disposed between the insulating liner and the insulating pattern. At least one of the insulating liner and the conductive liner includes a material having a two-dimensional network structure.

### CROSS-REFERENCE TO RELATED APPLICATION

This U.S. non-provisional patent application claims priority under 35 U.S.C. § 119 of Korean Patent Application No. 10-2025-0010308, filed on Jan. 23, 2025, the contents of which are hereby incorporated by reference in its entirety.

### BACKGROUND

Embodiments of the present disclosure described herein relate to an image sensor.

An image sensor includes a plurality of pixels arranged in a two-dimensional array. Each of the pixels includes a photodiode serving as a photoelectric conversion element. A device isolation pattern is formed between photoelectric conversion elements to separate the photoelectric conversion elements from one another. Since the device isolation pattern may provide a light absorption effect depending on materials, the amount of light reaching the photoelectric conversion elements may be reduced at a region adjacent to the device isolation pattern.

### SUMMARY

Embodiments of the present disclosure provide an image sensor with reduced light loss and improved light utilization efficiency, thereby enhancing photoelectric conversion efficiency.

Embodiments of the present disclosure provide an image sensor with reduced light loss, reduced dark current, and improved image quality.

According to an embodiment, an image sensor includes a semiconductor substrate including a first surface and a second surface opposite to the first surface, photodiodes defined in the semiconductor substrate, a photodiode (PD) isolation pattern extending vertically from one of the first surface and the second surface of the semiconductor substrate, and a microlens disposed on the second surface. The PD isolation pattern has a lattice-like configuration in a plan view. The PD isolation pattern includes an insulating pattern within the semiconductor substrate, a first insulating liner disposed between the insulating pattern and the semiconductor substrate, and a first conductive liner disposed between the first insulating liner and the insulating pattern. One of the first insulating liner and the first conductive liner includes a two-dimensional material.

According to an embodiment, an image sensor includes a semiconductor substrate and a PD isolation pattern disposed in an opening penetrating at least a portion of the semiconductor substrate. The PD isolation pattern includes an insulating liner covering a sidewall of the opening and a conductive liner covering a side surface of the insulating liner. One of the insulating liner and the conductive liner includes a material having a two-dimensional material. network structure. The PD isolation pattern has a lattice-like configuration in a plan view.

According to an embodiment, an image sensor includes a first substrate including a first surface and a second surface opposite to the first surface, a photodiode defined in the first substrate, a PD isolation pattern disposed in an opening penetrating through at least one of the first surface and the second surface of the first substrate, a microlens disposed on the second surface, and a first bonding pad disposed on the first surface and electrically connected to the photodiode. The image sensor further includes a second substrate, and The first substrate is stacked on a second substrate. The image sensor further a peripheral circuit provided with the second substrate, and a second bonding pad electrically connected to the peripheral circuit and in contact with the first bonding pad. The PD isolation pattern includes an insulating pattern disposed in the opening, an insulating liner disposed between the insulating pattern and the first substrate, and a conductive liner disposed between the insulating liner and the insulating pattern. One of the insulating liner and the conductive liner includes a material having a two-dimensional material. The PD isolation pattern has a lattice-like configuration in a plan view.

According to an embodiment, a method of manufacturing an image sensor includes preparing a semiconductor substrate including a first surface and a second surface opposite to the first surface, forming an opening penetrating through the first surface and/or the second surface, and forming a PD isolation pattern in the opening. The forming of the PD isolation pattern includes forming an insulating liner on a sidewall of the opening, forming a conductive liner on the insulating liner, filling an insulating pattern in the opening, and forming a photodiode element in the semiconductor substrate. At least one of the insulating liner and the conductive liner includes a material having a two-dimensional network structure.

The insulating liner includes hexagonal boron nitride (h-BN), and the conductive liner includes graphene.

At least one of the insulating liner and the conductive liner is formed through a chemical vapor deposition method.

The conductive liner includes polycrystalline silicon doped with a dopant, and the polycrystalline silicon is formed through an atomic layer deposition method.

The opening is formed in a direction from the first surface toward the second surface or in a direction from the second surface toward the first surface.

The method further includes forming multiple shallow trenches having a depth smaller than the opening.

When the shallow trenches are referred to as first openings and the openings are referred to as second openings, some of the first openings together with the second openings provide an interconnected space.

The insulating liner, the conductive liner, and the insulating pattern are formed in the interconnected space.

The method further includes forming the insulating liner and the conductive liner on the second surface.

According to the above, the image sensor having the device isolation pattern that is thinner than those in conventional image sensors is provided. As the device isolation pattern employs a material having minimal (or reduced) light absorption property, optical loss may be reduced. In addition, problems such as dark current may be reduced by applying a negative bias to the device isolation pattern. Accordingly, the photodiode efficiency of the image sensor may be improved and the degradation of the image may be significantly reduced.

### BRIEF DESCRIPTION OF THE DRAWINGS

The above and other objects and features of the present disclosure will become apparent by describing in detail embodiments thereof with reference to the accompanying drawings, wherein:

FIG. 1 is a block diagram illustrating an image sensor according to an embodiment of the present disclosure;

FIG. 2 is a circuit diagram illustrating pixels included in a pixel array of an image sensor according to an embodiment of the present disclosure;

FIG. 3 is a plan view illustrating an image sensor according to an embodiment of the present disclosure;

FIG. 4A is a cross-sectional view taken along a line A-A′ of FIG. 3;

FIG. 4B is an enlarged view illustrating a portion P1 of FIG. 4A;

FIG. 5 is a cross-sectional view illustrating an image sensor according to an embodiment of the present disclosure;

FIG. 6 is a cross-sectional view illustrating an image sensor according to an embodiment of the present disclosure;

FIG. 7 is a cross-sectional view illustrating an image sensor according to an embodiment of the present disclosure;

FIG. 8 is a cross-sectional view illustrating an image sensor according to an embodiment of the present disclosure;

FIGS. 9A to 9H are cross-sectional views sequentially illustrating a method of manufacturing an image sensor according to an embodiment of the present disclosure;

FIGS. 10A to 10H are cross-sectional views sequentially illustrating a method of manufacturing an image sensor according to an embodiment of the present disclosure; and

FIGS. 11A to 11H are cross-sectional views sequentially illustrating a method of manufacturing an image sensor according to an embodiment of the present disclosure.

### DETAILED DESCRIPTION

Hereinafter, embodiments of the present disclosure will be described with reference to accompanying drawings.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

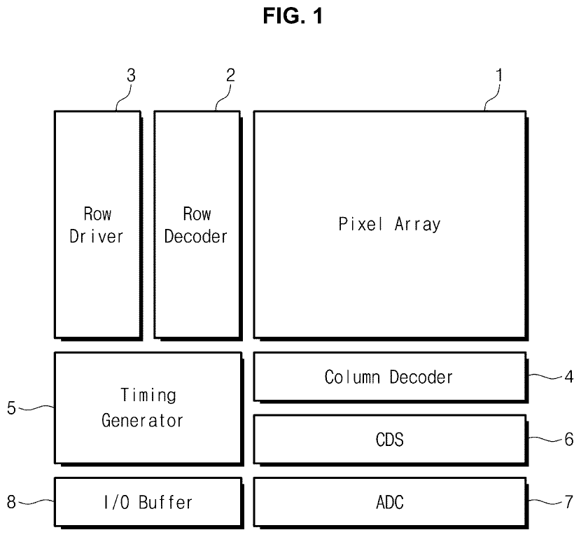

FIG. 1 is a block diagram illustrating an image sensor according to an embodiment of the present disclosure.

Referring to FIG. 1, the image sensor may include a pixel array 1, a row decoder 2, a row driver 3, a column decoder 4, a timing generator 5, a correlated double sampler (CDS) 6, an analog-to-digital (ADC) converter 7, and an input/output (I/O) buffer 8.

The pixel array 1 may include a plurality of pixels arranged in a two-dimensional array, and the pixels may convert optical signals into electrical signals. The pixel array 1 may be driven by a plurality of driving signals transmitted from the row driver 3, such as a pixel selection signal, a reset signal, and/or a charge transfer signal. The converted electrical signals may be provided to the correlated double sampler (CDS) 6.

The row driver 3 may provide the driving signals to the pixel array 1 to drive the pixels in accordance with the decoded result (or decoded information) from the row decoder 2. When the pixels are arranged in a matrix form, the driving signals may be provided on a row-by-row basis.

The timing generator 5 may provide a timing signal and a control signal to the row decoder 2 and the column decoder 4.

The correlated double sampler (CDS) 6 may receive the electrical signals generated by the pixel array 1 and may hold and sample the received signals. The correlated double sampler (CDS) 6 may perform double sampling on both a specific noise level and a signal level corresponding to electrical signals and may output a difference level corresponding to a difference between the noise level and the signal level.

The analog-to-digital (ADC) converter 7 may convert an analog signal corresponding to the difference level output from the correlated double sampler (CDS) 6 to a digital signal and may output the digital signal.

The input/output buffer 8 may latch digital signals and may sequentially output the latched signals to an image signal processor (not shown) based on the decoded result from the column decoder 4.

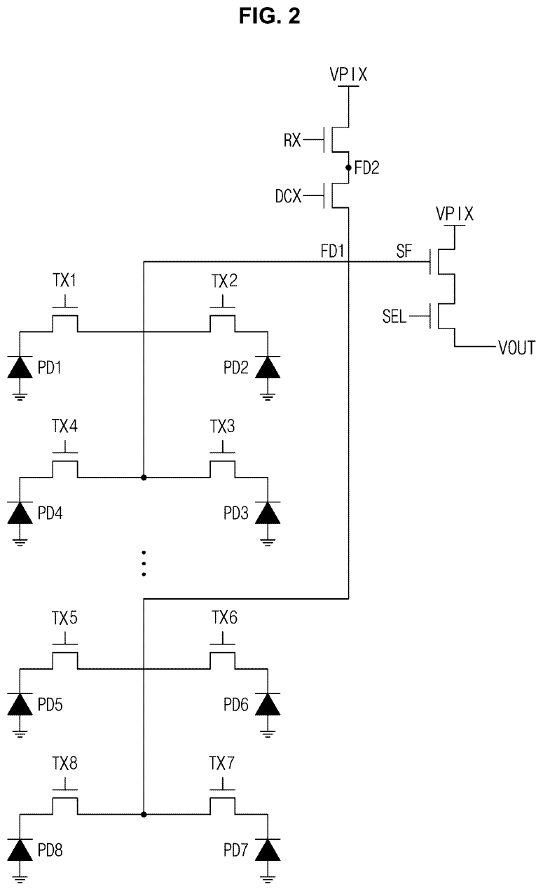

FIG. 2 is a circuit diagram for explaining a pixel structure of the pixel array.

Referring to FIG. 2, the pixel array may include a plurality of photodiodes PDn (n=1, 2, 3, . . . ), a plurality of transfer transistors TXm (m=1, 2, 3, . . . ), a first floating diffusion region FD1, a second floating diffusion region FD2, a reset transistor RX, a source follower transistor SF, a selection transistor SEL, and a dual conversion gain transistor DCX.

In some embodiments, the pixel array may have a shared pixel structure that includes a plurality of photodiodes PDn, for example, eight photodiodes or sixteen photodiodes. The eight photodiodes or the sixteen photodiodes may be divided into N groups arranged in an L×M matrix form in a plan view, and the N groups may be electrically connected to the first floating diffusion region FD1. Herein, L, M and N are natural numbers equal or greater than 1.

Each pixel described in example embodiments of this invention may include one photodiode PD and one microlens, two photodiodes and one microlens, or four photodiodes and one microlens. For example, the eight photodiodes may correspond to eight, four, or two pixels. For example, the sixteen photodiodes may correspond to sixteen, eight, or four pixels. The number of the transfer transistors TX may be eighth or sixteen. However, the number of photodiodes and the number of transfer transistors may not be limited thereto. The structural relationship between the pixels, microlens and the photodiodes is not limited to the specific ratios described in the specification and drawings, and may be modified or applied in various other configurations without departing from the spirit and scope of the invention.

Each of the photodiode PDn may be formed by forming an n-type semiconductor region in a substrate formed with a p-type semiconductor region and the photodiode PDn may convert incoming light into electric charges.

In some example embodiments, the first floating diffusion region FD1 may be connected to the second floating diffusion region FD2 by a dual conversion gain transistor DCX to adjust a combined capacitance.

The transfer transistors TXm may be driven by a predetermined bias, e.g., transfer signals. The transfer signals may be applied to a gate of each of the transfer transistors TXn to transfer the electric charges generated from the photodiodes PDn to first floating diffusion region FD1 according to the transfer signals.

The source follower transistor SF may amplify a change in electrical potential of the first floating diffusion region FD1 to which the electric charges are sent from the photodiodes PDn, and may output it to an output line VOUT. When the source follower transistor SF is turned on, a predetermined electrical potential provided to a drain of the source follower transistor SF, for example, a power supply voltage VPIX, may be sent (or transferred) to a drain region of the selection transistor SEL. In some example embodiments, a plurality of source follower transistors SFs may be connected to the first floating diffusion region FD1.

The selection transistor SEL may select a pixel to be read in units of a row. The selection transistor SEL may be driven by a selection line that applies a predetermined bias, e.g., a row selection signal. The row selection signal may be applied through a gate of the selection transistor SEL.

The reset transistor RX may periodically reset the first floating diffusion region FD1. When the reset transistor RX is turned on by a reset signal, a predetermined electrical potential provided to the drain of the reset transistor RX, for example, the power supply voltage VPIX, may be sent to the first floating diffusion region FD1.

The dual conversion gain transistor DCX may adjust the conversion gain. For example, the conversion gain may be adjusted, by applying a dual gain signal of a logic high level or applying a dual gain signal of a logic low level to a dual conversion gate of the dual conversion transistor DCX. The dual conversion gain transistor DCX may be provided between the first floating diffusion region FD1 and the second floating diffusion region FD2. The conversion gain may be adjusted, by adjusting the combined capacitance corresponding to the first floating diffusion regions FD1 and the second floating diffusion regions FD2 depending on whether the dual conversion gain transistor DCX is driven.

Although FIG. 2 shows an example in which eight or more photodiodes electrically share the first floating diffusion region FD1, example embodiments may not be limited thereto. For example, the number of photodiodes that electrically share the first floating diffusion region FD1 is not limited to that shown. In some example embodiments, the pixel array comprises a non-share pixel architecture in which one photodiode is connected to the first floating diffusion region FD1. For example, each photodiode may be electrically connected to a corresponding one of a plurality of transfer transistors, and each of a plurality of transfer transistors may be electrically connected to a corresponding one of a plurality of first floating diffusion regions FD1 and a corresponding one of a plurality of second floating diffusion regions FD2.

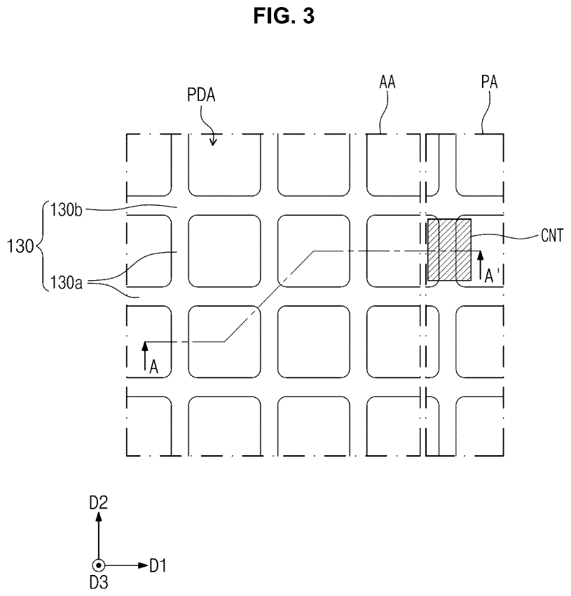

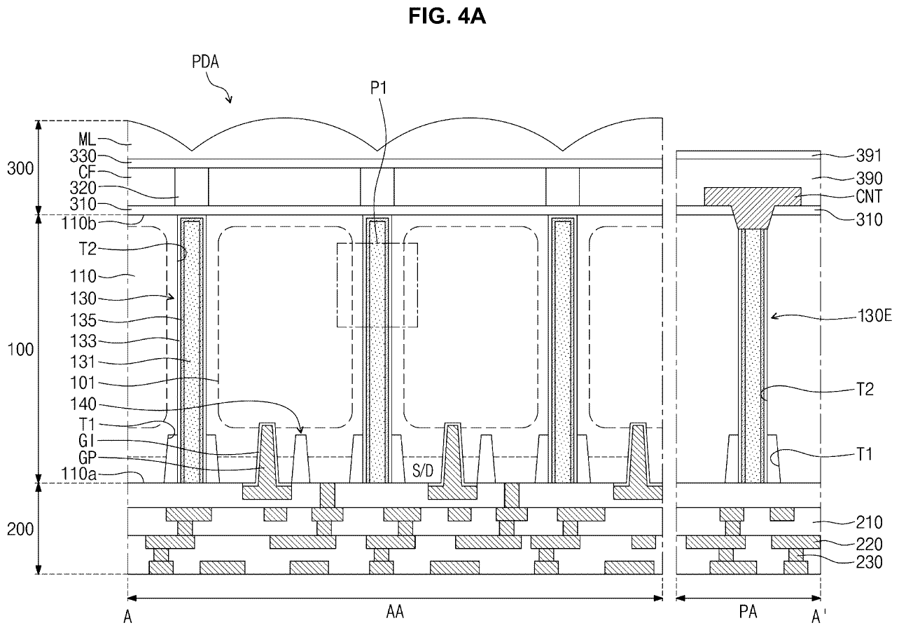

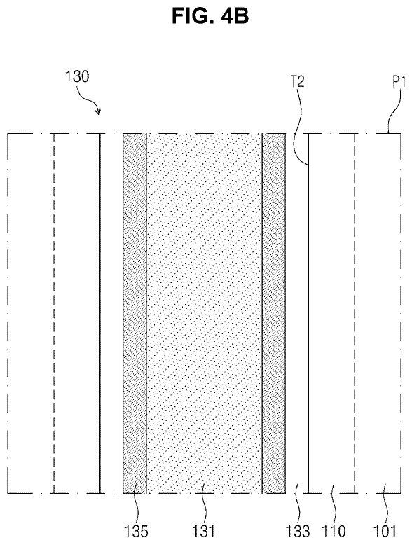

FIG. 3 is a plan view illustrating the image sensor according to an embodiment of the present disclosure. FIG. 4A is a cross-sectional view taken along a line A-A′ of FIG. 3. In the following description of the drawings, terms indicating directions, such as an upper side, an upper surface, an upper portion, a lower side, a lower surface, and a lower portion, are based on orientations shown in the drawings. It should be understood, however, that the terms may denote different directions depending on the inversion, rotation, or other modifications of the drawings. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Referring to FIGS. 3 and 4A, the photodiode elements (or photodiodes) may be arranged in the matrix form in a plan view, and photodiode regions PDA corresponding to the photodiode elements may be defined by a PD isolation pattern 130.

The PD isolation pattern 130 may include a side portion 130a extending in a row direction and a column direction (or in directions D1 and D2) and an intersection portion 130b provided in an area where one side portion 130a intersects with another side portion 130a in a plan view.

The photodiode regions PDA may have the same or different widths depending on their arrangement and positions. For example, a width of the PD isolation pattern 130 at the side portion 130a may differ from that at the intersection portion 130b. Hereinafter, for the convenience of explanation, a structure in which the side portion 130a and the intersection portion 130b of the PD isolation pattern 130 have substantially the same width will be described as an example.

The image sensor may include a photodiode layer 100, a circuit wiring layer 200, and a light transmission layer 300. The photodiode layer 100 may be disposed between the circuit wiring layer 200 and the light transmission layer 300.

The photodiode layer 100 may include a semiconductor substrate 110 including a first surface 110a and a second surface 110b facing away from the first surface 110a, the PD isolation pattern 130, shallow isolation patterns 140, and a photodiode element (or photodiodes) 101 defined in the semiconductor substrate 110. For example, the photodiodes 101 may be formed in the plurality of photodiode regions PDA.

The first surface 110a and the second surface 110b may face away from each other and may be referred to as a front surface and a rear surface, respectively. The light may be incident on the rear surface of the semiconductor substrate 110.

The semiconductor substrate 110 (or the image sensor) may include an active area AA and a peripheral area PA defined (or located) adjacent to the active area AA. The peripheral area PA may be disposed at at least one side of the active area AA or may surround the active area AA in a plan view. The active area AA of the semiconductor substrate 110 may correspond to the pixel array in which the photodiode regions PDA are arranged.

The semiconductor substrate 110 may be a silicon substrate, a germanium substrate, a silicon-germanium substrate, a Group II-VI compound semiconductor substrate, a Group III-V compound semiconductor substrate, or a silicon-on-insulator (SOI) substrate. The semiconductor substrate 110 may include a first conductive type dopant, and accordingly, the semiconductor substrate 110 may have a first conductivity type. The first conductive type dopant may be a Group III element. As an example, the first conductive type dopant may include p-type dopants such as aluminum (Al), boron (B), indium (In), and/or gallium (Ga).

The photodiode regions PDA may be arranged in the matrix form along a first direction D1 and a second direction D2 intersecting with the first direction D1.

The PD isolation pattern 130 may penetrate through the semiconductor substrate 110. For example, the PD isolation pattern 130 may extend vertically (or in a third direction D3) from one of the first surface 110a and the second surface 110b of the semiconductor substrate 110. The PD isolation pattern 130 may be provided in a second trench (or second opening) T2 formed in the semiconductor substrate 110. The second trench T2 may penetrate through the semiconductor substrate 110 along the third direction D3 that is perpendicular to the first surface 110a. The PD isolation pattern 130 may penetrate through the semiconductor substrate 110 along the formation direction of the second trench T2, for example, along the third direction D3 perpendicular to the first surface 110a. In an embodiment, the PD isolation pattern 130 may extend from the first surface 110a toward the second surface 110b. In some embodiments, the second trench T2 and the PD isolation pattern 130 may penetrate partially through the semiconductor substrate 110.

A lower surface of the PD isolation pattern 130 may be coplanar with the first surface 110a, and an upper surface of the PD isolation pattern 130 may be coplanar with the second surface 110b. However, the present disclosure should not be limited thereto or thereby. In an embodiment, at least a portion of the upper surface and/or the lower surface of the PD isolation pattern 130 may protrude from or may be recessed from the plane defined by the second surface 110b and/or the plane defined by the first surface 110a.

The PD isolation pattern 130 may include the side portion 130a extending in the row direction and the column direction and the intersection portion 130b provided in the area where one side portion 130a intersects with another side portion 130a. For example, the PD isolation pattern 130 may have a lattice-like configuration in a plan view. The side portion 130a may correspond to sides facing each other of two adjacent photodiode regions PDA, and the intersection portion 130b may correspond to corners facing each other of four adjacent photodiode regions PDA.

The PD isolation pattern 130 will be described in detail with reference to FIG. 4B.

Each of the photodiode regions PDA may include the photodiode element 101. The photodiode elements 101 may be disposed between the first surface 110a and the second surface 110b of the semiconductor substrate 110. The photodiode elements 101 may be or include doped regions containing a second conductive type dopant that is opposite to the first conductive type dopant. In an embodiment of the present disclosure, the photodiode elements 101 may include a Group V element as a dopant, and the Group V element may be the second conductive type dopant. For example, the photodiode elements 101 may be doped regions formed to be the second conductive type (e.g., n-type). The second conductive type dopant may include n-type dopants such as phosphorus (P), arsenic (As), bismuth (Bi), and/or antimony (Sb). The photodiode element 101 may form a P-N junction with the semiconductor substrate 110 to form a photodiode. Although the P-N junction is a junction between the photodiode element 101 and the semiconductor substrate 110, the photodiode element 101 may be simply referred to as “photodiode.”

The shallow isolation patterns 140 may be arranged adjacent to (or at) the first surface 110a. The shallow isolation patterns 140 may extend into the semiconductor substrate 110 from the first surface 110a and may be buried in (e.g., formed on and recessed into) the semiconductor substrate 110. In cross sectional views, the shallow isolation patterns 140 may be provided in first trenches (or first openings) T1 formed in the semiconductor substrate 110.

The shallow isolation patterns 140 may be to provide electrical and/or physical isolation between adjacent components. A portion of each of the shallow isolation patterns 140 may be provided within a corresponding one of the photodiode regions where pixels are formed and may be spaced apart from the PD isolation pattern 130 in a cross sectional view.

A portion of each of the shallow isolation patterns 140 may be provided at an edge of each photodiode region PDA. In some embodiments, the portion of the shallow isolation patterns 140 may vertically overlap with the PD isolation pattern 130. In some embodiments, the portion of the shallow isolation patterns 140 may be in contact with the PD isolation pattern 130 even when the portion of the shallow isolation patterns 140 does not vertically overlap with the PD isolation pattern 130. In an embodiment, the PD isolation pattern 130 may penetrate through a portion of the shallow isolation patterns 140, and a portion of a side surface of the PD isolation pattern 130 may be in contact with a portion of a side surface of the shallow isolation patterns 140.

A lower surface of the shallow isolation patterns 140 may be substantially coplanar with the first surface 110a, however, the present disclosure should not be limited thereto or thereby. In an embodiment, unlike the structure shown in figures, at least a portion of the lower surface of the shallow isolation patterns 140 may protrude from or may be recessed from the plane defined by the first surface 110a.

The shallow isolation patterns 140 may be formed of various insulating materials, and, as an example, may include at least one of a silicon oxide layer, a silicon nitride layer, and a silicon oxynitride layer.

The circuit wiring layer 200 may be provided on the first surface 110a of the semiconductor substrate 110. The circuit wiring layer 200 may include a circuit part including a gate pattern GP and a gate insulating layer GI, contact vias 230 connected to the circuit part, and conductive lines 220. The contact vias 230 and the conductive lines 220 may be provided on or in interlayer insulating layers 210 stacked on the first surface 110a. The interlayer insulating layers 210 may cover the first surface 110a, the upper surface of the PD isolation pattern 130, and the upper surface of the shallow isolation patterns 140. The interlayer insulating layers 210 may also cover transistors forming the circuit part. The conductive lines 220 may be electrically connected to the transistors of the circuit part through the contact vias 230. The interlayer insulating layers 210 may include an insulating material, and the contact vias 230 and the conductive lines 220 may include a conductive material. In some embodiments, the circuit wiring layer 200 and the photodiode layer 100 may share a transistor which includes a gate pattern GP and a gate insulating layer GI. For example, the photodiode layer 100 may include a source/drain region S/D, a part of the gate pattern GP and a part of the gate insulating layer GI. The source/drain region S/D may be formed in (as part of) the semiconductor substrate 110 such that impurities (charge carrier dopants) may be introduced into the substrate 110. The substrate 110 may not be materially distinctive from the source/drain region S/D. Reference to the source/drain region S/D being provided with the substrate 110 is referred to with the intention of encompassing these embodiments. Similarly, reference to a transistor being provided with the substrate 110 is referred to with the intention of encompassing these embodiments. Similarly, reference to the circuit wiring layer 200 (or peripheral circuit) being provided with the substrate 110 is referred to with the intention of encompassing these embodiments. In a similar manner, a plurality of peripheral transistors may be formed in (or provided with) the peripheral area PA (though not shown in the drawings).

The gate pattern GP may be disposed on the first surface 110a of the semiconductor substrate 110. The gate pattern GP may function as a gate electrode of the transfer transistor, the source-follower transistor, the reset transistor, or the selection transistor to drive the image sensor. For example, the gate patterns GP may include a transfer gate, a source-follower gate, a reset gate, or a selection gate. In the drawings, for convenience of explanation, one gate pattern GP is shown as being disposed in each photodiode region PDA, however, the present disclosure should not be limited thereto or thereby. According to an embodiment, a plurality of gate patterns GP may be disposed in each photodiode region PDA. As shown in figures, the gate pattern GP may have a buried gate structure, but it should not be limited thereto or thereby. Alternatively, the gate pattern GP may have a planar gate structure. The gate pattern GP may include a metal material, a metal silicide material, polycrystalline silicon, or a combination thereof.

The gate insulating layer GI may be interposed between the gate pattern GP and the semiconductor substrate 110. The gate insulating layer GI may include, for example, a silicon-based insulating material such as silicon oxide, silicon nitride, and/or silicon oxynitride, and/or a high-k dielectric material such as hafnium oxide and/or aluminum oxide.

The light transmission layer 300 may be disposed on the second surface 110b of the semiconductor substrate 110. The light transmission layer 300 may be a layer through which light traveling from the outside toward the photodiode element 101 transmits. The second surface 110b of the semiconductor substrate 110 may serve as a light incident surface. The light transmission layer 300 may include color filters CF, a grid 320, and microlenses ML, which are disposed on the second surface 110b. The color filters CF may be disposed between the second surface 110b and the microlenses ML. The light transmission layer 300 may collect and filter the light incident from the outside and may provide the light to the photodiode layer 100.

The color filters CF may be disposed on the photodiode regions PDA, respectively. According to embodiments, four photodiode regions PDA arranged in a two by two (2×2) array may implement the same color. Alternatively, the four photodiode regions PDA arranged in a two by two (2×2) configuration may implement one of red, green, and blue colors. As an example, the four photodiode regions PDA may implement red, green, green, and blue colors in sequence.

The color filters CF may be disposed on the second surface 110b of the semiconductor substrate 110 to respectively correspond to the photodiode regions PDA. For example, the color filters CF may be respectively provided at positions corresponding to the photodiode elements 101. Each of the color filters CF may be selected from among a plurality of reference colors. The reference colors may include, for example, RGB (red, green, blue), RGBW (red, green, blue, white), CMY (cyan, magenta, yellow), CMYK (cyan, magenta, yellow, black), RYB (red, yellow, blue), or RGBIR (infrared ray). However, the colors of the color filters CF should not be limited thereto or thereby, and other color filters may also be used. The color filters CF may form color filter arrays.

The grid 320 may be disposed on the PD isolation pattern 130. The grid 320 may vertically overlap the PD isolation pattern 130.

The grid 320 may have a shape corresponding to the PD isolation pattern 130. As an example, the grid 320 may have a grid-like (or lattice-like) shape in a plan view. The grid 320 may surround the color filters CF in a plan view. The grid 320 may be arranged such that at least a portion thereof overlaps with the PD isolation pattern 130 vertically (e.g., in the third direction D3).

The grid 320 may be interposed between two color filters CF adjacent to each other. The color filters CF may be physically and optically separated from each other by the grid 320. Accordingly, the grid 320 may guide the light incident on the second surface 110b to be incident into the photodiode element 101.

The grid 320 may include a metal, but it should not be limited thereto or thereby. According to an embodiment, the grid 320 may include a low refractive index material. The low refractive index material may include a polymer and silica nanoparticles dispersed within the polymer. The low refractive index material may have insulating properties. According to an embodiment, the grid 320 may include a metal and/or a metal nitride. For example, the grid 320 may include titanium and/or titanium nitride.

The microlenses ML may be disposed above the color filters CF. At least a portion of each of the microlenses ML may be arranged to overlap with a corresponding one of the photodiode elements 101 vertically (e.g., in the third direction D3). The microlenses ML may collect light traveling in a direction toward the semiconductor substrate 110 and may be spherical lenses, aspherical lenses, or a combination thereof. The microlenses ML may be provided at positions corresponding to the photodiode elements 101 of the semiconductor substrate 110.

The microlens ML may be transparent and may transmit light. The microlens ML may include an organic material such as a polymer. As an example, the microlens ML may include a photoresist material or a thermosetting resin.

In an embodiment of the present disclosure, the color filters CF, the grids 320, and/or the microlenses ML are described as overlapping with positions corresponding to each pixel PX (or each photodiode region PDA), however, the present disclosure should not be limited thereto or thereby. According to an embodiment, at least one of the color filters CF, the grids 320, and the microlenses ML may have an offset structure that is shifted by a predetermined amount from the position corresponding to each pixel PX. The offset structure may result from process margins of the color filters CF, the grids 320, and/or the microlenses ML or may be intentionally designed to optimize a light path in consideration of factors, such as an angle of the light traveling to the pixels PX from the outside.

A light control layer 310 may be interposed between the second surface 110b of the semiconductor substrate 110 and the color filters (CF) and between the PD isolation pattern 130 and the grid 320. The light control layer 310 may cover the second surface 110b of the semiconductor substrate 110 and the upper surface of the PD isolation pattern 130. The light control layer 310 may include an anti-reflective layer. The anti-reflective layer is formed to prevent or significantly reduce reflection of the incident light, which is caused by abrupt changes in refractive index of components located between the outside and the photodiode element 101. Accordingly, the light control layer 310 may prevent or significantly reduce the reflection of light incident on the second surface 110b of the semiconductor substrate 110 to allow the light to reach the photodiode element 101 more efficiently. The term “anti-reflective” does not necessarily mean that reflection is completely eliminated, but rather that reflection is reduced to a desired level.

In an embodiment, the light control layer 310 may include a plurality of layers. In an embodiment, the light control layer 310 may further include a negative fixed charge layer. When the light control layer 310 includes the negative fixed charge layer, an additional effect of preventing or reducing the dark current by stable charge accumulation near the second surface 110b of the semiconductor substrate 110 may be obtained.

The light control layer 310 may be formed from various materials, for example, hafnium oxide (HfOx), zirconium oxide (ZrO2), titanium oxide (TiO2), aluminum oxide (Al2O3, alumina), etc.

A contact portion (or pattern) CNT may be provided in (or on) the peripheral area PA of the semiconductor substrate 110. The contact portion CNT may be disposed on or adjacent to the second surface 110b and may be partially buried into (e.g., formed on and partially recessed into) the semiconductor substrate 110. The contact portion CNT may be in contact with an upper surface of a conductive liner 135, which will be described later.

Although not shown in figures, the contact portion CNT may include a metal pattern extending into the semiconductor substrate 110 from the above of the light control layer 310 and a barrier pattern surrounding the metal pattern. In some embodiments, a contact insulating layer may be provided on an outer portion of the contact portion CNT to surround the contact portion CNT. Although not shown in figures, the contact portion CNT may horizontally extend to another region and may be electrically connected to a TSV (Through-Silicon Via) or a BVS (Back Via Stack). As a result, a negative bias voltage may be applied to the conductive liner 135 through the contact portion CNT, and thus, white spots or dark current may be prevented or suppressed from occurring or may be reduced. A bulk color filter 390 and a protective layer 391 may be sequentially provided on the contact portion CNT in (or on) the peripheral area PA.

FIG. 4B is an enlarged view illustrating a portion P1 of FIG. 4A to show the PD isolation pattern.

Referring to FIGS. 4A and 4B, the PD isolation pattern 130 may include an insulating pattern, such as a buried insulating pattern 131, the conductive liner 135, and an insulating liner 133, which are provided in the second trench T2 penetrating through the first surface 110a and the second surface 110b of the semiconductor substrate 110.

The PD isolation pattern 130 may penetrate through the first surface 110a and the second surface 110b. The PD isolation pattern 130 may extend in a direction from the first surface 110a to the second surface 110b.

The buried insulating pattern 131 may be filled in at least a portion of a space in the second trench T2.

The buried insulating pattern 131 may be formed of an insulating material having excellent gap-filling properties, such as an oxide including silicon oxide, silicon nitride, and/or silicon oxynitride. However, the material of the buried insulating pattern 131 should not be limited thereto or thereby. According to an embodiment, the buried insulating pattern 131 may include at least one of a boro-phospho silicate glass (BPSG) layer, a high density plasma (HDP) oxide layer, a flowable chemical vapor deposition (FCVD) layer, an ozone-tetraethyl orthosilicate (O3-TEOS) layer, an undoped silicate glass (USG) material, a tonen silazene (TOSZ) material, etc.

In an embodiment of the present disclosure, the buried insulating pattern 131 may be selected from materials having relatively low light absorbance. As an example, the buried insulating pattern 131 may be formed of a material having lower light absorbance than doped or undoped silicon.

In an embodiment of the present disclosure, at least one of the insulating liner 133 and the conductive liner 135 may include a material with a two-dimensional network structure. The material with the two-dimensional network structure may be a material with a two-dimensional crystal structure. The material with the two-dimensional network structure may have an extremely thin thickness compared to a material with a three-dimensional crystal structure and may exhibit various physical properties depending on the material. In an embodiment of the present disclosure, the insulating liner 133 may include an insulating material with the two-dimensional network structure, and the conductive liner 135 may include a conductive material with the two-dimensional network structure. In an embodiment of the present disclosure, since at least one of the insulating liner 133 and the conductive liner 135 includes the material with the two-dimensional network structure, the PD isolation pattern 130 may be formed to an extremely thin thickness.

For example, at least one of the insulating liner 133 and the conductive liner 135 may include a two-dimensional material. The two-dimensional material may be formed as a sheet having a nanoscopic thickness. The two-dimensional material may be a very thin layer, e.g., one or two atoms (or molecules) thick. The material may have crystal structure. The two-dimensional material may exhibit unique electrical, mechanical, and optical properties due to its reduced dimensionality, as compared to a bulk material of the same composition, for example, graphene relative to graphite.

For example, each of the insulating liner 133 and the conductive liner 135 may have an end portion that is terminated by an open end, thereby forming a U-shaped configuration in a cross-sectional view. Two vertical sidewalls of each of the insulating liner 133 and the conductive liner 135 may extend vertically in parallel, defining an inner hollow region between them. The open termination of each of the insulating liner 133 and the conductive liner 135 may provide an exposed end of the inner region in a cross-sectional view.

The insulating liner 133 may be interposed between the conductive liner 135 and the semiconductor substrate 110 and may electrically insulate the semiconductor substrate 110 from the conductive liner 135. The insulating liner 133 may surround a periphery of each photodiode region PDA in a plan view. The insulating liner 133 may penetrate through the first surface 110a and the second surface 110b. For example, the insulating liner 133 may extend from the first surface 110a to the second surface 110b, and lower and upper surfaces of the insulating liner 133 may be substantially coplanar with the first surface 110a and the second surface 110b, respectively. However, positions of the lower and upper surfaces of the insulating liner 133 should not be limited thereto or thereby, and according to another embodiment, the lower and upper surfaces of the insulating liner 133 may be provided at planes different from the first surface 110a and the second surface 110b, respectively.

In some embodiments, though not shown in the drawings, the insulating liner 133 may be provided on a sidewall of the second trench T2. The insulating liner 133 may at least partially cover the second surface 110b (or the first surface 110a) of the semiconductor substrate 110 and the sidewall within the second trench T2, which penetrates through the second surface 110b of the semiconductor substrate 110. An upper portion of the insulating liner 133 may be provided on a lower surface of the light control layer 310. In an embodiment, unlike what is shown in FIG. 4A, the second trench T2 may not completely but partially penetrate the semiconductor substrate 110. In this case, the second trench T2 may have a shape extending in a direction from the first surface 110a toward the second surface 110b, and the upper surface of the insulating liner 133 may be spaced apart from the second surface 110b of the semiconductor substrate 110.

The insulating liner 133 may include a stable insulating material in which dangling bonds are absent or minimized or significantly reduced. For example, the insulating liner 133 may include boron nitride. In an embodiment, the insulating liner 133 may include hexagonal boron nitride (h-BN) among the various forms of boron nitride. The hexagonal boron nitride (h-BN) may have a layered graphite-like structure, e.g., the two-dimensional network structure in which boron and nitrogen atoms within each layer are strongly bonded covalently. For example, the h-BN may be a two-dimensional material. Adjacent layers of the h-BN may be held together by weak van der Waals forces. The hexagonal boron nitride (h-BN) may have a structure similar to graphene having a honeycomb lattice structure, e.g., with almost identical dimensions. Unlike graphene, the hexagonal boron nitride (h-BN) may be an insulator and may be used as a dielectric material. The insulating liner 133 including boron nitride, such as the hexagonal boron nitride, may provide sufficient insulating performance even at a significantly reduced thickness compared to conventional insulating materials. In an embodiment, the hexagonal boron nitride may provide an insulation effect substantially equivalent or similar to that of silicon oxide with a thickness of several nanometers to several tens of nanometers, even when formed at a thickness on the order of several tens to several hundreds of angstroms, for example, less than 1 nanometer. In general, h-BN may or may not be regarded as a two-dimensional material, depending on its thickness. For example, monolayer or few-layer h-BN is recognized as a two-dimensional material exhibiting unique properties compared with a bulk (three-dimensional) material. In contrast, bulk h-BN is generally considered a three-dimensional layered solid and may not be regarded as a two-dimensional material.

The conductive liner 135 may be interposed between the semiconductor substrate 110 and the buried insulating pattern 131. The conductive liner 135 may surround the periphery of the photodiode regions PDA where, e.g., each pixel is provided in a plan view. The conductive liner 135 may be disposed on the upper surface of the insulating liner 133.

The conductive liner 135 may include a conductive material. For example, the conductive liner 135 may be formed of two-dimensional material. For example, graphene inherently represents a two-dimensional material. Graphene may be an allotrope of carbon composed of an extremely thin layer of carbon atoms arranged in a hexagonal honeycomb lattice. It, as a two-dimensional structure, may exhibit distinct properties compared with bulk carbon. In an embodiment, the conductive liner 135 may include a conductive material with a two-dimensional network structure. Graphene may be used as the conductive material with the two-dimensional network structure. Graphene not only has the two-dimensional structure but also exhibits high electrical conductivity and high transparency. When the conductive liner 135 is formed of graphene, the conductive liner 135 may be formed to a relatively thinner thickness compared to when the conductive liner 135 is formed of materials such as dopant-doped silicon, metals, or metal oxides. In addition, when the conductive liner 135 is formed of graphene, the conductive liner 135 may exhibit a relatively higher light transmittance compared with conductive liners made from the materials such as dopant-doped silicon, metals, or metal oxides.

In an embodiment, the conductive liner 135 may be doped with a conductive material or doped with charge carrier dopants. The conductive material may include crystalline silicon. The crystalline silicon may be a thin layer formed by an atomic layer deposition (ALD).

The conductive liner 135 may receive a negative bias voltage through the contact portion CNT and may function to stabilize hole accumulation near its interface in an area adjacent to the PD isolation pattern 130.

In an embodiment of the present disclosure, each of the conductive liner 135 and the insulating liner 133 is shown as a single layer, but the present disclosure should not be limited thereto. For example, the conductive liner 135 and/or the insulating liner 133 may each be a composite layer including a plurality of layers. In an embodiment, the conductive liner 135 may include at least one conductive layer formed of a material such as a metal or a metal oxide in addition to a conductive layer including graphene. In an embodiment, the insulating liner 133 may include at least one insulating layer formed of silicon oxide or silicon nitride, for example, SiN, SiCN, or SiOCN, in addition to an insulating layer including a boron nitride layer as a two-dimensional material. Since the conductive liner 135 and/or the insulating liner 133 include layers having the two-dimensional network structure, even when they are formed in a multi-layer structure (or formed of a composite layer), the conductive liner 135 and/or the insulating liner 133 may have a much thinner thickness than those formed only of layers having the three-dimensional structure.

In an embodiment of the present disclosure, each of the conductive liner 135 and the insulating liner 133 are shown as being provided on the light control layer 310 to cover the lower surface of the light control layer 310, however, the present disclosure should not be limited thereto. According to an embodiment, each of the conductive liner 135 and the insulating liner 133 may have other configurations. For example, the conductive liner 135 and the insulating liner 133 may not be provided on the light control layer 310. In this case, the buried insulating pattern 131 may penetrate completely through the semiconductor substrate 110 and may be provided on the light control layer 310. For example, unlike the U-shaped configuration discussed above, each of the insulating liner 133 and the conductive liner 135 may have end portions that are terminated by open ends at both the first surface 110a and the second surface 110b. The open termination of each of the insulating liner 133 and the conductive liner 135 may provide an exposed end of the inner region at both the first surface 110a and the second surface 110b in a cross-sectional view.

According to an embodiment of the present disclosure, as shown in FIG. 4A, the negative bias voltage may be applied to the PD isolation pattern 130 through the contact portion CNT provided in (or on) the peripheral area PA. According to an embodiment, a wiring connected to the conductive liner 135 may be separately provided in the circuit wiring layer 200 disposed under the PD isolation pattern 130.

For example, the PD isolation pattern may have an extension portion 130E positioned in the peripheral area PA. The extension portion 130E may include an extension portion of the buried insulating pattern 131, an extension portion of the conductive liner 135, and an extension portion of the insulating liner 133. Each of the extension portions may be integrally connected to the other portion of a corresponding one of the buried insulating pattern 131, the conductive liner 135 and the insulating liner 133. The contact portion CNT may be in contact with and/or electrically connected to the extension portion of the conductive liner 135. Accordingly, the negative bias voltage may be applied to the entire portion of the conductive liner 135. At least one of the shallow isolation patterns 140 may be disposed adjacent to (and/or in contact with) the extension portion 130E.

For example, unlike the U-shaped configuration discussed above, each of the extension portion of the conductive liner 135 and the extension portion of the insulating liner 133 may have end portions that are terminated by open ends. The contact portion CNT may be in contact with the open termination of each of the extension portion of the conductive liner 135 and the extension portion of the insulating liner 133 in a cross-sectional view.

The image sensor having the above-described structure may reduce both the dark current problem and the incident light loss. This effect will be described in detail as follows.

In the image sensor, one of the main causes of a dark level is the dark current, which is generated by the undesirable accumulation of electrons at the interface between the PD isolation pattern 130 and the photodiode element 101. To reduce problems caused by the generation of the dark current, it is desirable to capture (or reduce or repel) the electrons generated at the interface between the PD isolation pattern 130 and the photodiode element 101, thereby preventing or suppressing the electrons from moving into the photodiode element 101. To this end, in a conventional related art, a conductive isolation layer is formed by filling polycrystalline silicon into a trench, and a negative bias voltage is applied to the conductive isolation layer, thereby suppressing the dark current.

However, when polycrystalline silicon is filled into the trench and used as the conductive isolation layer, there is a problem in that the polycrystalline silicon conductive isolation layer absorbs incident light. Since polycrystalline silicon has a relatively higher light absorption rate compared to the insulating material, such as silicon oxide, or air, the amount of light reaching the photodiode element 101 of the image sensor may be reduced, and thus, the sensitivity of the image sensor may be deteriorated.

In the present disclosure, graphene is employed as the conductive liner 135 instead of polycrystalline silicon while the negative bias voltage is still applied to the PD isolation pattern 130, and thus, the absorption of light travelling into each photodiode element 101 may be minimized or reduced. In particular, graphene, as a conductive material, may be used to apply the negative bias voltage (in a similar manner to applying a negative voltage to polycrystalline silicon in the conventional art) and may be provided in an extremely thin thickness. In addition, unlike polycrystalline silicon, graphene does not require a silicon dopant doping process using plasma, for example, a p-type dopant doping process. For example, the plasma process may cause a problem in view of device reliability.

Accordingly, the dark current preventing or suppressing effect achieved by the conventional polycrystalline silicon may be sufficiently obtained through the conductive liner 135 of the present disclosure, and since the dopant doping process using plasma is not needed, there is no risk induced by shrinking the photodiode element. In addition, according to embodiments of the present disclosure, since the insulating liner 133 and the conductive liner 135 are formed far thinner than those in the conventional PD isolation pattern, a light transmittance may significantly increase compared to that of the PD isolation pattern including polycrystalline silicon. Further, in an embodiment of the present disclosure, the buried insulating pattern 131 may be formed in the second trench T2 using a material that has a lower light absorption rate than polycrystalline silicon, such as silicon oxide, and thus, the light absorption caused by the use of polycrystalline silicon may be prevented or suppressed.

For the reasons described above, according to the embodiment of the present disclosure, the area of the photodiode element 101 may be maximized or increased within the image sensor, which leads to an increase in a full well capacity (FWC) of the image sensor.

As a result, since the negative bias is applied to the conductive liner 135, problems in the image sensor, which are caused by dark current, may be prevented or suppressed, and the light absorption rate, associated with (or as compared to) the conventional polycrystalline silicon, may be minimized or reduced. In addition, since the buried insulating pattern 131 having the high light transmittance is employed, the loss of light incident to the photodiode element 101 may be reduced. Further, since the loss of incident light is reduced, the photodiode efficiency may be improved, and the sensitivity of the image sensor may be enhanced.

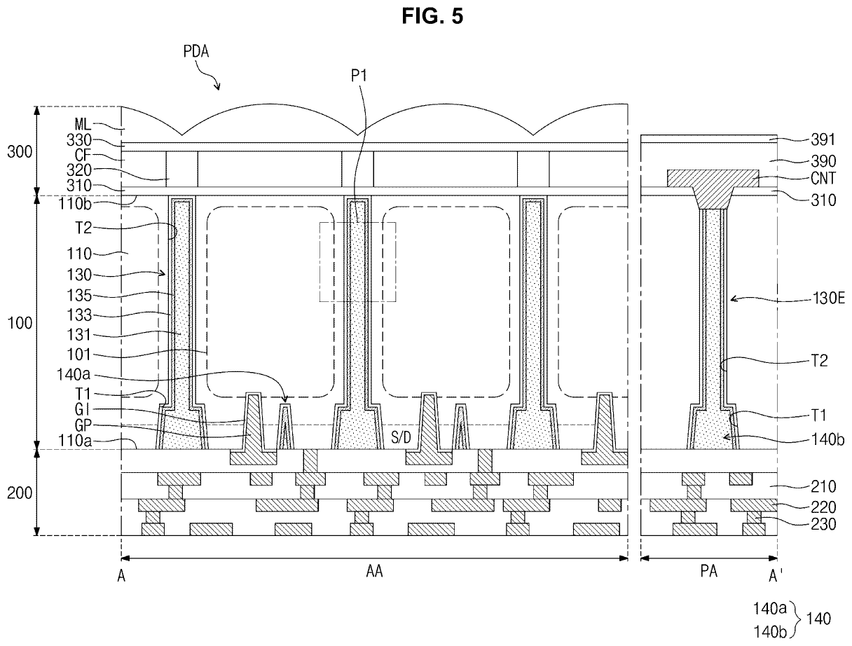

FIG. 5 is a cross-sectional view illustrating an image sensor taken along a line A-A′ of FIG. 3 according to an embodiment of the present disclosure. A portion P1 of FIG. 5 corresponds to the portion P1 of FIG. 4B and has substantially the same structure as (or substantially similar structure to) that of the portion P1 of FIG. 4B. Hereinafter, different features from those of the above embodiments will be mainly described in order to avoid redundancy.

Referring to FIGS. 5 and 4B, a PD isolation pattern 130 may penetrate through a semiconductor substrate 110. The PD isolation pattern 130 may be disposed in a second trench T2 in the semiconductor substrate 110. The PD isolation pattern 130 may extend from a first surface 110a to a second surface 110b.

Shallow device isolation patterns (or shallow isolation patterns) 140 may be arranged adjacent to the first surface 110a. The shallow isolation patterns 140 may extend from the first surface 110a to the inside of the semiconductor substrate 110 and may be buried in (e.g., formed on and recessed into) the semiconductor substrate 110. The shallow isolation patterns 140 may be provided in a first trench T1 (e.g., in respective first shallow trenches) in the semiconductor substrate 110.

In a cross sectional view, the shallow isolation patterns 140 may include first shallow isolation patterns (which may be first shallow isolation portions) 140a respectively disposed in photodiode regions PDA and a second shallow isolation pattern (or second shallow isolation portions) 140b disposed at edges of the photodiode regions PDA. The first shallow isolation patterns 140a may be spaced apart from the PD isolation pattern 130 in the cross sectional view. For example, each of the shallow isolation patterns 140 may include the first shallow isolation portion 140a disposed in corresponding one of the plurality of photodiode regions PDA in a cross sectional view, and my include a second shallow isolation portion 140b disposed at an edge of the corresponding one of the plurality of photodiode regions PDA in the cross sectional view.

The second shallow isolation patterns 140b may be formed integrally with the PD isolation pattern 130 without being separated from the PD isolation pattern 130. In more detail, the second shallow isolation pattern 140b and the PD isolation pattern 130 may be provided in a space defined by the first trench T1 and the second trench T2 connected to the first trench T1.

For example, each of the second shallow isolation portions 140b may be provided integrally with one of the insulating pattern 131, the insulating liner 133 and the conductive liner 135 of the PD isolation pattern 130. Each of the first shallow isolation portions 140a and/or each of the second shallow isolation portions 140b may include an insulating pattern, which is formed integrally with the insulating pattern of the PD isolation pattern 130. Each of the first shallow isolation portions 140a and/or each of the second shallow isolation portions 140b may include a conductive liner, which is formed integrally with the conductive liner of the PD isolation pattern 130. Each of the first shallow isolation portions 140a and/or each of the second shallow isolation portions 140b may include an insulating liner, which is formed integrally with the insulating liner of the PD isolation pattern 130.

The buried insulating patterns of the second shallow isolation pattern 140b and the PD isolation pattern 130 may be collectively referred to as a PD isolation pattern 130. The insulating liners of the second shallow isolation pattern 140b and the PD isolation pattern 130 may be collectively referred to as an insulating liner 133. The conductive liners of the second shallow isolation pattern 140b and the PD isolation pattern 130 may be collectively referred to as a conductive liner 135.

The second shallow isolation pattern 140b and the PD isolation pattern 130 may include a buried insulating pattern 131, a conductive liner 135, and an insulating liner 133, which are provided in the second trench T2.

The second shallow isolation pattern 140b and the PD isolation pattern 130 may share at least a portion of the buried insulating pattern 131, the conductive liner 135, and the insulating liner 133. Alternatively, each of the second shallow isolation pattern 140b and the PD isolation pattern 130 may include the buried insulating pattern 131, the conductive liner 135, and the insulating liner 133, and components provided within the second shallow isolation pattern 140b and the PD isolation pattern 130 may be in contact with or physically connected to each other. For example, the buried insulating pattern 131, the conductive liner 135, and the insulating liner 133 provided in the second shallow isolation pattern 140b and the PD isolation pattern 130 may be provided integrally without being separated.

In an embodiment, the buried insulating pattern 131 provided in the second shallow isolation pattern 140b and the PD isolation pattern 130 may extend in a direction from the first surface 110a to the second surface 110b. The buried insulating pattern 131 may be filled in the first trench T1 and the second trench T2. In an embodiment, a lower surface of the buried insulating pattern 131 may be coplanar with the first surface 110a, and an upper surface of the buried insulating pattern 131 may be coplanar with the second surface 110b. According to an embodiment, the lower surface of the buried insulating pattern 131 may not be coplanar with the first surface 110a, and the upper surface of the buried insulating pattern 131 may not be coplanar with the second surface 110b.

The insulating liner 133 provided in the second shallow isolation pattern 140b and the PD isolation pattern 130 may be formed along sidewalls of the combination of the first trench T1 and the second trench T2. The insulating liner 133 provided in the second shallow isolation pattern 140b and the PD isolation pattern 130 may conformally cover the sidewalls of the first trench T1 and the second trench T2.

The insulating liner 133 may include a stable insulating material in which dangling bonds are absent or minimized or significantly reduced. For instance, the insulating liner 133 may include boron nitride as a two-dimensional material. In an embodiment, the insulating liner 133 may include hexagonal boron nitride (h-BN) among the various forms of boron nitride.

The conductive liner 135 may be interposed between the insulating liner 133 and the buried insulating pattern 131. The conductive liner 135 may surround a periphery of each photodiode region PDA in a plan view.

The conductive liner 135 may include a conductive material. In an embodiment, the conductive liner 135 may include a conductive material having a two-dimensional network structure. For example, the conductive liner 135 may include a two-dimensional material. As an example, graphene may be used as the conductive material having the two-dimensional network structure. According to an embodiment, the conductive liner 135 may include polycrystalline silicon doped with a conductive material or doped with charge carrier dopants.

In an embodiment, the first shallow isolation patterns 140a may also include the insulating liner 133, the conductive liner 135, and the buried insulating pattern 131. For example, the first shallow isolation pattern 140a may have substantially the same material configuration as that of the second shallow isolation pattern 140b and/or the PD isolation pattern 130. In a cross sectional view, the first shallow isolation pattern 140a may have different shape and/or dimension (e.g., height) from those of the second shallow isolation patterns 140b and/or the PD isolation pattern 130.

The buried insulating pattern 131 provided in the first shallow isolation patterns 140a may fill a portion of the first trench T1. The insulating liner 133 provided in the first shallow isolation patterns 140a may be formed along the sidewalls of the first trench T1. The insulating liner 133 provided in the first shallow isolation pattern 140a may conformally cover the sidewalls of the first trench T1. The conductive liner 135 provided in the first shallow isolation patterns 140a may be interposed between the insulating liner 133 and the buried insulating pattern 131.

The buried insulating patterns 131 in the first shallow isolation patterns 140a and the second shallow isolation pattern 140b may include the same material and/or be formed integrally without a distinct boundary therebetween. In addition, the conductive liners 135 in the first shallow isolation patterns 140a and the second shallow isolation pattern 140b may also include the same material and/or be formed integrally without a distinct boundary therebetween, and the insulating liners 133 in the first shallow isolation patterns 140a and the second shallow isolation pattern 140b may also include the same material and/or be formed integrally without a distinct boundary therebetween. In an embodiment, the first shallow isolation patterns 140a, the second shallow isolation pattern 140b, and the PD isolation pattern 130 may be formed through the same process. This will be described in detail later.

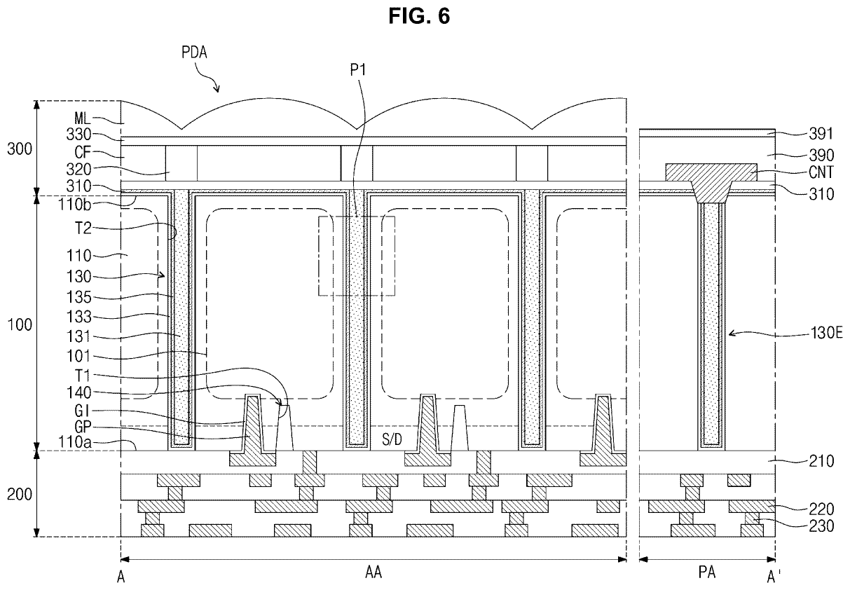

FIG. 6 is a cross-sectional view illustrating an image sensor taken along a line A-A′ of FIG. 3 according to an embodiment of the present disclosure. A portion P1 of FIG. 6 corresponds to the portion P1 of FIG. 4B and has substantially the same structure as (or substantially similar structure to) that of the portion P1 of FIG. 4B.

Referring to FIGS. 6 and 4B, a PD isolation pattern 130 may penetrate through a semiconductor substrate 110. The PD isolation pattern 130 may be disposed in a second trench T2 in the semiconductor substrate 110. The PD isolation pattern 130 may extend from a second surface 110b to a first surface 110a.

Shallow device isolation patterns 140 may be arranged adjacent to the first surface 110a. The shallow isolation patterns 140 may extend from the first surface 110a to the inside of the semiconductor substrate 110 and may be buried in (e.g., formed on and recessed into) the semiconductor substrate 110. The shallow isolation patterns 140 may be provided in a first trench T1 in the semiconductor substrate 110.

The shallow isolation patterns 140 may be disposed respectively in photodiode regions PDA. The shallow isolation patterns 140 may be spaced apart from the PD isolation pattern 130 in a plan view. The shallow isolation patterns 140 may not be disposed at an edge of the photodiode regions PDA in a cross sectional view.

The shallow isolation patterns 140 may include an oxide layer including silicon oxide, silicon nitride, and/or silicon oxynitride. However, the materials of the shallow isolation patterns should not be limited thereto or thereby.

The PD isolation pattern 130 may include a buried insulating pattern 131, a conductive liner 135, and an insulating liner 133, which are provided in the second trench T2.

The buried insulating pattern 131 may be formed of an insulating material having excellent gap-filling properties and may include, for example, an oxide including silicon oxide as well as silicon nitride and/or silicon oxynitride. However, the buried insulating pattern 131 should not be limited thereto or thereby.

The insulating liner 133 may be interposed between the conductive liner 135 and the semiconductor substrate 110 and may electrically insulate the semiconductor substrate 110 from the conductive liner 135. In a plan view, the insulating liner 133 may surround a periphery of each photodiode region PDA. The insulating liner 133 may penetrate through the first surface 110a and the second surface 110b. For example, the insulating liner 133 may extend from the second surface 110b to the first surface 110a.

The insulating liner 133 may be provided on sidewalls of the second trench T2. The insulating liner 133 may cover both the second surface 110b of the semiconductor substrate 110 and the sidewalls and a lower surface of the second trench T2, which penetrates through the second surface 110b of the semiconductor substrate 110. The second trench T2 may completely penetrate through the semiconductor substrate 110, and in this case, a lower portion of the insulating liner 133 may be in contact with the first surface 110a. In an embodiment, the lower portion of the insulating liner 133 may be provided on an upper surface of an interlayer insulating layer 210. Unlike the structure shown in FIG. 4A, the second trench T2 may not completely but partially penetrate the semiconductor substrate 110. In this case, the second trench T2 may have a shape extending from the second surface 110b toward the first surface 110a, and the lower portion of the insulating liner 133 may be spaced apart from the second surface 110b of the semiconductor substrate 110.

The insulating liner 133 may include a stable insulating material in which dangling bonds are absent or minimized or significantly reduced. For instance, the insulating liner 133 may include boron nitride. In an embodiment, the insulating liner 133 may include hexagonal boron nitride (h-BN) as a two-dimensional material among the various forms of boron nitride.

The conductive liner 135 may be interposed between the semiconductor substrate 110 and the buried insulating pattern 131. The conductive liner 135 may surround the periphery of each photodiode region PDA in a plan view. The conductive liner 135 may be provided on an upper surface of the insulating liner 133.

The conductive liner 135 may include a conductive material. In an embodiment, the conductive liner 135 may include a conductive material as a two-dimensional material. For example, the conductive liner 135 may include a conductive material having a two-dimensional network structure. As an example, graphene may be used as the conductive material having the two-dimensional network structure. The graphene may have the two-dimensional structure and high electrical conductivity as well as high transparency resulting therefrom. The conductive liner 135 may include polycrystalline silicon doped with a conductive material or doped with charge carrier dopants. The doped polycrystalline silicon may be a thin film formed by atomic layer deposition (ALD).

The conductive liner 135 may receive a negative bias voltage through a contact portion CNT and may serve to stabilize hole accumulation near an interface of the conductive liner 135 in an area adjacent to the PD isolation pattern 130.

In the present embodiment, the conductive liner 135 and the insulating liner 133 in the PD isolation pattern 130 may extend not only into spaces within the second trenches T2 but also onto the second surface 110b of the semiconductor substrate 110. The insulating liner 133 and the conductive liner 135 may be sequentially stacked on the second surface 110b of the semiconductor substrate 110 to cover at least a portion of the second surface 110b of the semiconductor substrate 110.

The insulating liner 133 and the conductive liner 135 covering the second surface 110b of the semiconductor substrate 110 may be integrally formed with the conductive liner 135 and the insulating liner 133 provided in the PD isolation pattern 130 without being separated. For example, the insulating liner 133 and the conductive liner 135 covering the second surface 110b of the semiconductor substrate 110 may be in contact with or physically connected to the buried insulating pattern 131, the conductive liner 135, and the insulating liner 133, which are provided in the PD isolation pattern 130. For example, the insulating liner 133 may extend continuously from inside of the second trenches (or trench) T2 and onto the second surface 110b of the semiconductor substrate 110, thereby covering at least a portion of the second surface 110b.

Since the insulating liner 133 and the conductive liner 135 are provided on the second surface 110b of the semiconductor substrate 110, it is possible to further obtain (or enhance) the effect of preventing or suppressing the dark current by stable charge accumulation near the second surface 110b of the semiconductor substrate 110.

In an embodiment, when the insulating liner 133 and the conductive liner 135 are provided on the second surface 110b of the semiconductor substrate 110, the light control layer 310 may not include a negative fixed charge layer having a negative charge, but include an anti-reflective layer. For example, the light control layer 310 may include an anti-reflective layer without a fixed charge layer.

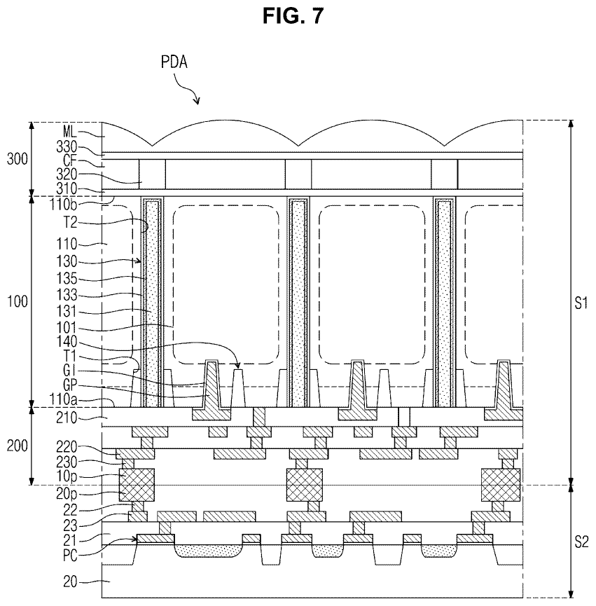

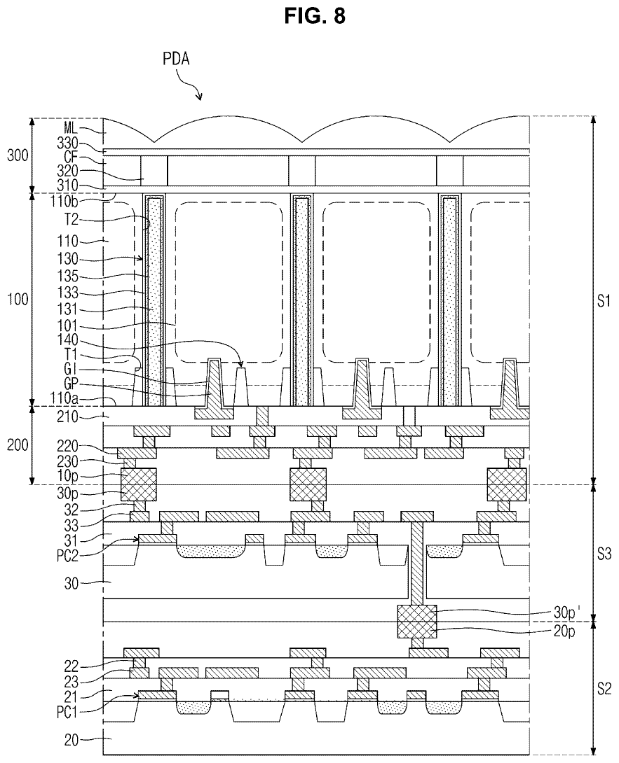

FIGS. 7 and 8 are cross-sectional views illustrating image sensors according to embodiments of the present disclosure.

Referring to FIGS. 7 and 8, the image sensors according to the embodiments of the present disclosure may have various structures. As an example, the image sensor may be formed as a single structure, but may also include multiple-stacked structures such as a first structure S1 and a second structure S2 as shown in FIG. 7. In some embodiments, when the image sensor includes the first structure S1 and the second structure S2, some components included in pixels may be provided in the first structure S1, and the remaining components may be provided in the second structure S2. For example, a photodiode element, a transfer transistor, and a floating diffusion region may be provided in the first structure S1, and the other transistors, such as a reset transistor, a source-follower transistor, and a selection transistor, may be provided in the second structure S2. Alternatively, the image sensor may include first, second, and third structures S1, S2, and S3 as shown in FIG. 8. In this case, the second and/or third structures S2 and S3 may include logic circuits that control the pixels. The logic circuits may include circuits to process pixel signals from the pixels. As an example, the logic circuits may include a control register block, a timing generator, a row driver, a read-out circuit, a ramp signal generator, and an image signal processor.

In an embodiment of the present disclosure, a memory device may further be disposed (or embedded) in the second structure S2 and/or third structures S3. As the memory device, a dynamic random access memory (DRAM) device, a static random access memory (SRAM) device, a spin transfer torque magnetic random access memory (STT-MRAM) device, or a flash memory device may be formed in an embedded manner. The image sensor may temporarily store frame images using the memory devices and may perform signal processing. Thus, a jello effect (for example, image wobbling caused by rolling shutter operation) may be minimized or reduced, and operational characteristics of the image sensor may be improved. Further, since the memory device of the image sensor is formed in an embedded manner together with logic elements, the manufacturing process may be simplified and the overall size of products may be reduced.

Referring again to FIG. 7, the image sensor may include the first and second structures S1 and S2. The first structure S1 may be stacked on the second structure S2. For example, the image sensor may have a stacked structure. The first structure S1 may also be referred to as a photodiode structure, and the second structure S2 may be referred to as a peripheral circuit structure. The first structure S1 and the second structure S2 may be bonded to each other by at least one of various bonding methods and may be electrically connected to each other by at least one of various connection methods.

The first structure S1 may include a light transmission layer 300, a photodiode layer 100, and a circuit wiring layer 200. The photodiode layer 100 may be disposed between the light transmission layer 300 and the circuit wiring layer 200. The first structure S1 may correspond to the image sensors described in the embodiments of FIGS. 4A, 5, and 6, or a combination thereof. Hereinafter, for convenience of explanation, the semiconductor substrate 110 of the first structure S1 will be referred to as a first substrate 110.

In detail, the light transmission layer 300 may include microlenses ML, a color filter CF, a light control layer 310, a grid 320, and an insulating layer 330. The photodiode layer 100 may include the first substrate 110, photodiode elements 101, a PD isolation pattern 130, and shallow isolation patterns 140. The circuit wiring layer 200 may include a circuit part including a gate pattern GP and a gate insulating layer GI, interlayer insulating layers 210, conductive lines 220, contact vias 230, and a first bonding pad 10p.

The interlayer insulating layers 210 may cover a first surface 110a, an upper surface of the PD isolation pattern 130, and upper surfaces of the shallow isolation patterns 140. The interlayer insulating layers 210 may also cover transistors forming the circuit part. The conductive lines 220 may be electrically connected to the transistors of the circuit part through the contact vias 230. The interlayer insulating layers 210 may include an insulating material, and the contact vias 230 and the conductive lines 220 may include a conductive material.

The first bonding pads 10p may be disposed in the interlayer insulating layer located at a lowermost position among the interlayer insulating layers 210.

The second structure S2 may include interlayer insulating layers 21, peripheral circuits PC, conductive lines 22, contact vias 23, and second bonding pads 12p.

The interlayer insulating layers 21 in the second structure S2 may be provided on a second substrate 20. The interlayer insulating layers 21 may cover an upper surface of the second substrate 20 and the peripheral circuits PC. For instance, each of the interlayer insulating layers 21 may include at least one of silicon oxide, silicon oxynitride, or silicon nitride. In an embodiment, the interlayer insulating layers 21 may be sequentially stacked on the second substrate 20. The conductive lines 22 and the contact vias 23 may be provided in the interlayer insulating layers 21.

The second bonding pad 20p may be disposed in the interlayer insulating layer located at an uppermost position among the interlayer insulating layers 21 in the second structure S2.

The first and second bonding pads 10p and 20p may electrically connect the first and second structures S1 and S2. In an embodiment, the first bonding pad 10p and the second bonding pad 20p may be bonded to each other to electrically connect the first structure S1 and the second structure S2. In an embodiment, the first and second bonding pads 10p and 20p may include copper. The first and second bonding pads 10p and 20p may be bonded to each other using a copper-to-copper bonding technique. The bonding pads 10p and 20p may be bonded to each other such that bonding pads 10p and 20p are provided integrally with each other without an interface therebetween. In an embodiment, the lowermost interlayer insulating layer 210 of the first structure S1 may be bonded to the uppermost interlayer insulating layers 21 of the second structure S2 through covalent bonding.

FIG. 8 is a cross-sectional view illustrating the image sensor according to an embodiment of the present disclosure.

Referring to FIG. 8, the image sensor may include the first, second, and third structures S1, S2, and S3. The first structure S1 may be stacked on the third structure S3, and the third structure S3 may be stacked on the second structure S2. For example, the third structure S3 may be disposed between the first structure S1 and the second structure S2. The third structure S3 may also be referred to as an intermediate structure. The first structure S1 and the third structure S3 may be bonded to each other by at least one of various bonding methods and may be electrically connected to each other by at least one of various connection methods. Similarly, the second structure S2 and the third structure S3 may be bonded to each other by at least one of various bonding methods and may be electrically connected to each other by at least one of various connection methods.

The third structure S3 may include interlayer insulating layers 31, peripheral circuits PC, conductive lines 32, contact vias 33, and third bonding pads 30p and 30p′.

The interlayer insulating layers 31 in the third structure S3 may be provided on a third substrate 30. The interlayer insulating layers 31 in the third structure S3 may cover an upper surface of the third substrate 30 and the peripheral circuits. For example, each of the interlayer insulating layers 31 may include at least one of silicon oxide, silicon oxynitride, or silicon nitride. In an embodiment, the interlayer insulating layers 31 may be sequentially stacked on third substrate 30. The conductive lines 32 and the contact vias 33 may be provided in the interlayer insulating layers 31.

The third substrate 30 may include an upper surface facing the first structure S1 and a lower surface facing the second structure S2.

In some embodiments, gates, such as a reset gate, a selection gate, and a source follower gate, may be disposed in corresponding areas of the third substrate 30. In an embodiment, the reset gate, the selection gate, and the source follower gate may be disposed on an upper surface of the third substrate 30. Source/drain areas may be respectively disposed in corresponding areas at opposite sides of each of the gates in a cross sectional view.

At least one of the interlayer insulating layers 31 in the third structure S3 may be disposed on the upper surface of the third substrate 30 and may cover the reset gate, the selection gate, and the source follower gate. In an embodiment, the multiple interlayer insulating layers 31 may be sequentially stacked on the upper surface of the third substrate 30. At least another one of the interlayer insulating layers 31 may be disposed on a lower surface of the third substrate 30.

Among the third bonding pads 30p and 30p′ of the third structure S3, pads 30p may be disposed on the upper surface of the third substrate 30, and pads 30p′ may be disposed on the lower surface of the third substrate 30. As an example, the pad 30P among the third bonding pads 30p and 30p′ may be disposed in an uppermost one of the interlayer insulating layers 31 disposed on the upper surface of the third substrate 30, and the pad 30p′ among the third bonding pads 30p and 30p′ may be disposed in a lowermost one of the interlayer insulating layers 31 disposed on the lower surface of the third substrate 30.

The first, second, and third bonding pads 10p, 20p, 30p, and 30p′ may electrically connect the first, second, and third structures S1, S2, and S3. In an embodiment, the first bonding pad 10p and a portion of the third bonding pads 30p and 30p′ may be bonded to each other to electrically connect the first structure S1 and the third structure S3. In an embodiment, the second bonding pad 20p and a portion of the third bonding pads 30p and 30p′ may be bonded to each other to electrically connect the second structure S2 and the third structure S3.

In an embodiment, the third structure S3 may be bonded in a manner different from those illustrated in FIG. 8, for example, after being flipped vertically, flipped both vertically and horizontally, or rotated by 180°.

In an embodiment, the third bonding pads 30p and 30p′ may include copper, like the first and second bonding pads 10p and 20p. Among the first, second, and third bonding pads 10p, 20p, 30p, and 30p', those that are bonded to each other may be bonded using a copper-to-copper bonding technique, and the bonding pads may be bonded to each other such that the bonding pads are provided integrally with each other without an interface therebetween.

In an embodiment, the bonded layers among the interlayer insulating layers 210, 21, and 31 in each structure may be joined to one another by covalent bonding. As an example, the lowermost one of the interlayer insulating layers 210 of the first structure S1 may be bonded to the uppermost one of the interlayer insulating layers 31 of the third structure S3. As an example, the uppermost one of the interlayer insulating layers 21 of the second structure S2 may be bonded to the lowermost one of the interlayer insulating layers 31 of the third structure S3.

In an embodiment, the third structure S3 is also bonded after being inverted (not shown in the figures, e.g., the vertical inversion, the vertical and horizontal inversion, or the 180° rotation).

In FIGS. 7 and 8, the copper-to-copper bonding technique is described as an example for the bonding of the first structure S1, the second structure S2, and/or the third structure S3, but this is merely for convenience of explanation and should not be limited thereto or thereby. The first structure S1, the second structure S2, and/or the third structure S3 may be connected through various element connection structures, such as connectors, bonding wires, bumps, and the like other than the copper-to-copper bonding technique.

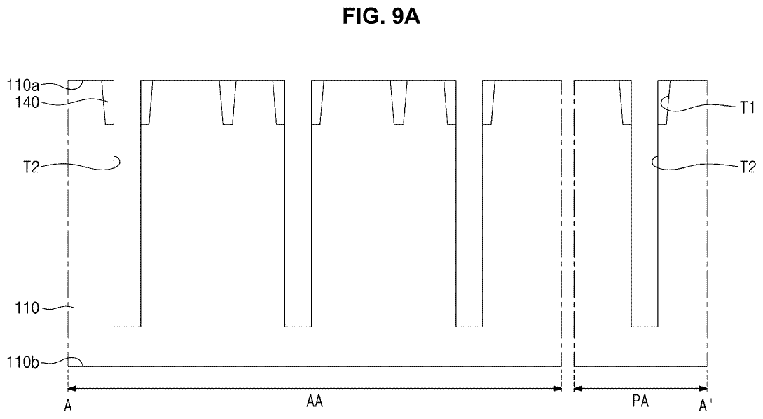

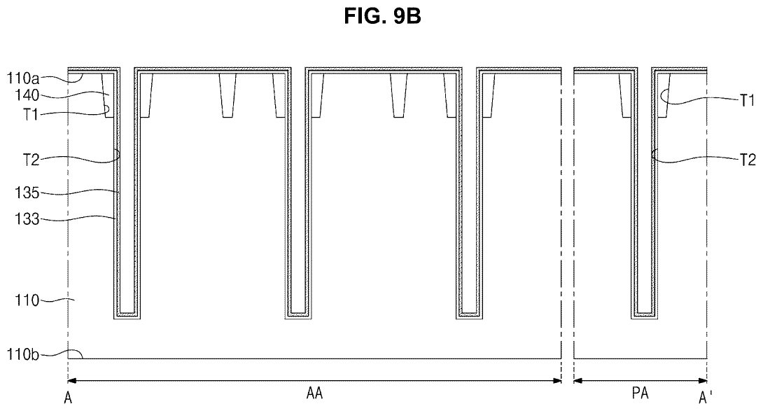

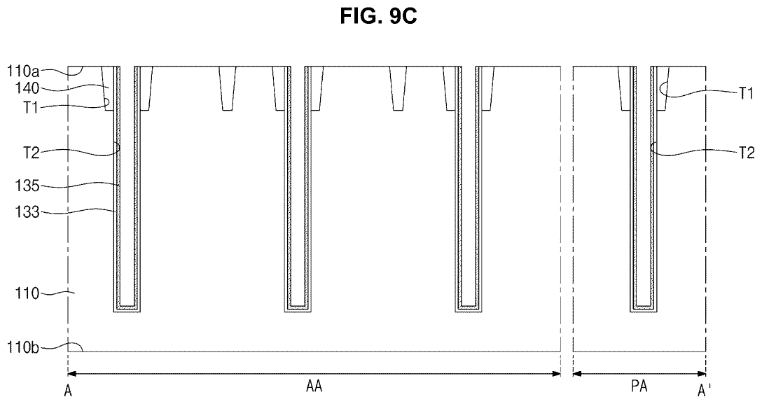

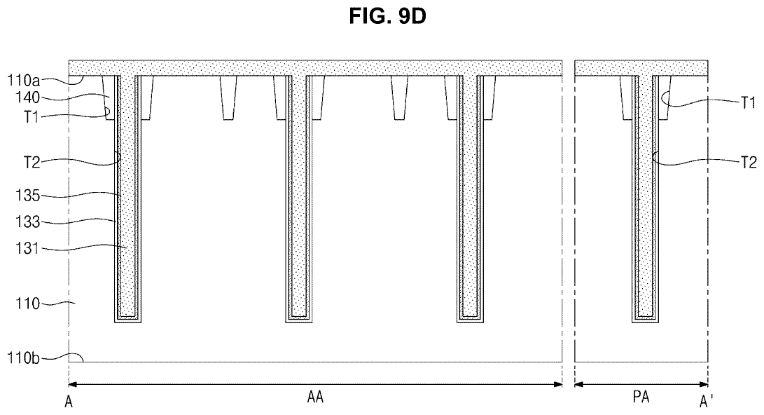

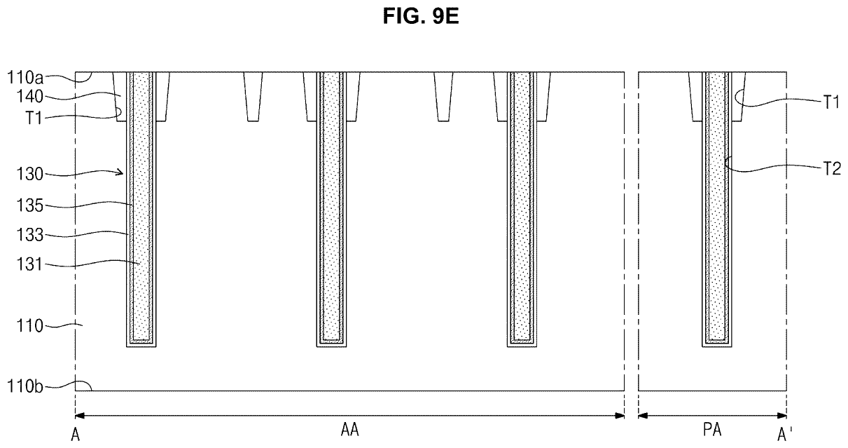

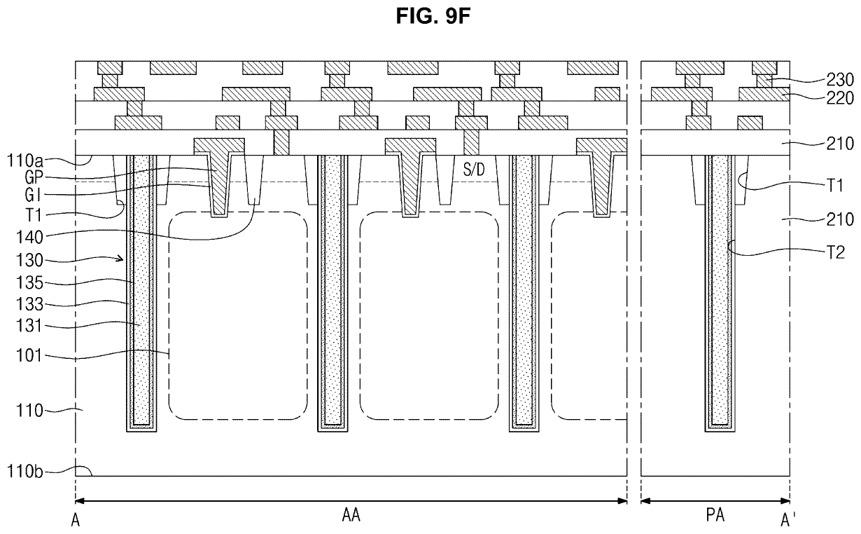

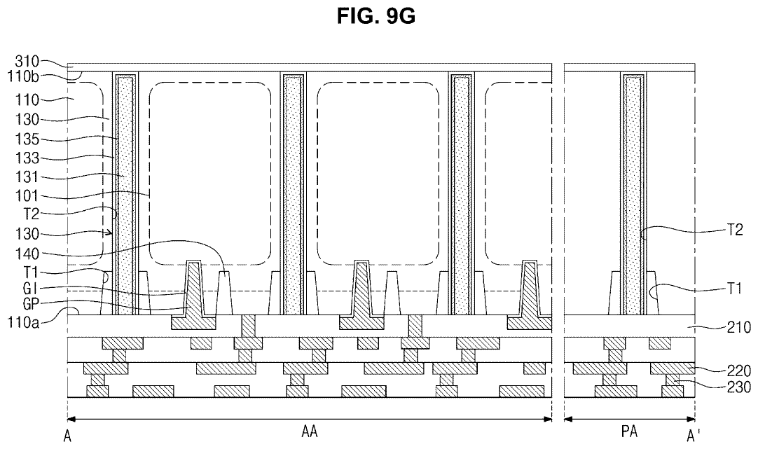

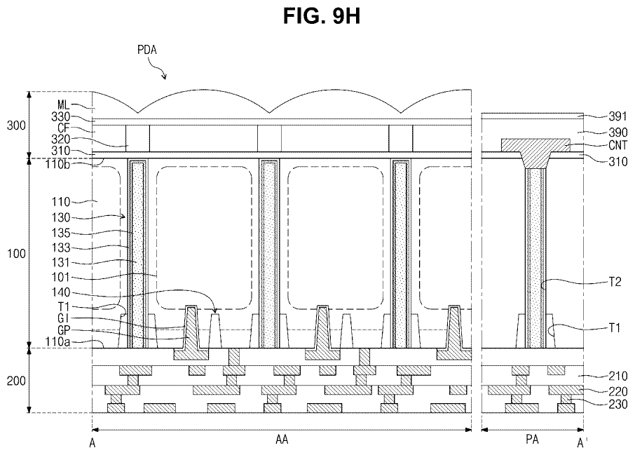

FIGS. 9A to 9H are cross-sectional views sequentially illustrating a method of manufacturing the image sensor according to an embodiment of the present disclosure.

FIGS. 9A to 9H are cross-sectional views sequentially illustrating the manufacturing process of the image sensor according to an embodiment of the present disclosure and corresponding to FIG. 4A. For example, FIGS. 9A to 9H may show intermediate structures of the embodiment corresponding to that shown in FIG. 4A. For convenience of explanation, the manufacturing process of the image sensor according to the embodiment of the present disclosure is described with reference to the embodiment shown in FIGS. 4A and 4B, and details that are the same as those described above are omitted.

Referring to FIG. 9A, the semiconductor substrate 110 including the first and second surfaces 110a and 110b opposite to each other may be provided. The shallow isolation patterns 140 may be formed adjacent to the first surface 110a of the semiconductor substrate 110 and may be buried in (e.g., formed on and recessed into) the semiconductor substrate 110.

The shallow isolation patterns 140 may be formed by forming the first trench T1 recessed from the first surface 110a of the semiconductor substrate 110 and then filling the first trench (or opening) T1. The shallow isolation patterns 140 may be formed of an insulating material and may include a silicon oxide layer, a silicon nitride layer, and/or a silicon oxynitride layer.

The second trench (or opening) T2 may be formed in the semiconductor substrate 110 in which the shallow isolation patterns 140 are formed. In an embodiment, the second trench T2 may extend into the inside of the semiconductor substrate 110 from the first surface 110a of the semiconductor substrate 110. The second trench T2 may be formed by forming a mask pattern that defines an area in which the PD isolation pattern 130 is to be formed and etching the shallow isolation patterns 140 and the semiconductor substrate 110 using the mask pattern.

Referring to FIG. 9B, the insulating liner 133 may be formed in the semiconductor substrate 110 in which the second trench T2 is formed. The insulating liner 133 may cover an inner wall of the second trench T2 and may conformally cover the upper surface of the semiconductor substrate 110 on which the shallow isolation patterns 140 and the like are formed.

The insulating liner 133 may include the stable insulating material in which dangling bonds are absent or minimized or significantly reduced. For instance, the insulating liner 133 may include boron nitride. In an embodiment, the insulating liner 133 may be formed by a chemical vapor deposition (CVD) process, however, the method of forming the insulating liner 133 should not be limited thereto or thereby.

For example, the insulating liner 133 may include hexagonal boron nitride (h-BN) as a two-dimensional material. A nucleation-promoting (catalytic/activation) treatment may be performed on the substrate 110. Subsequently h-BN may be formed by chemical vapor deposition using borazine or ammonia-borane. Where a temporary catalytic metal is used, it may be subsequently removed so that h-BN remains. The h-BN thickness may be controlled to be sufficiently thin (e.g., monolayer or few-layer) to exhibit two-dimensional material characteristics.

The conductive liner 135 may be formed on the semiconductor substrate 110 on which the insulating liner 133 is formed. The conductive liner 135 may conformally cover an inner wall of the insulating liner 133 in the second trench T2 and the upper surface of the semiconductor substrate 110.

The conductive liner 135 may be formed of a conductive material. In an embodiment, the conductive liner 135 may include the conductive material having the two-dimensional network structure. Graphene may be used as the conductive material having the two-dimensional network structure.

In an embodiment, the conductive liner 135 may be formed by a chemical vapor deposition (CVD) process. However, the method of forming the conductive liner 135 should not be limited thereto or thereby. For example, the graphene film may be formed by chemical vapor deposition by using a mixture of methane and hydrogen with argon as a carrier gas to be supplied on the substrate 110. A nucleation-promoting treatment and a solid-carbon activation step may be performed. Where a temporary catalytic metal is employed, it may thereafter be removed so that graphene remains on the substrate 110. The graphene thickness is controlled to be sufficiently thin (e.g., monolayer or few-layer) to exhibit two-dimensional material characteristics.

In an embodiment, the conductive liner 135 may include the semiconductor material doped with the first conductive type dopant or the second conductive type dopant, for example, polycrystalline silicon doped with boron or phosphorus. When the conductive liner 135 includes polycrystalline silicon, the conductive liner 135 may be formed by an atomic layer deposition (ALD). When using the atomic layer deposition (ALD), the conductive liner 135 may be formed to a relatively thin thickness compared to other processes.

However, the method of forming the conductive liner 135 should not be limited thereto or thereby, and other methods may be employed as long as the conductive liner 135 may be formed to a sufficiently thin thickness on the insulating liner 133. As an example, the conductive liner 135 may be formed by at least one of processes in which a semiconductor material and a dopant are mixed and then deposited, such as a low-pressure chemical vapor deposition (LPCVD) or a plasma-enhanced chemical vapor deposition (PECVD), or by at least one of processes in which a semiconductor material is deposited and then a dopant is introduced, such as an ion implantation process, a plasma doping process, or a gas phase doping process. In this case, a silicon seed treatment using diisopropylamino silane (DIPAS) and/or hexachlorodisilane (HCDS) may be performed immediately before the deposition of the materials for the conductive liner 135 to achieve the highest possible (or improved) conformality of the conductive liner 135 within the second trench T2.

Referring to FIG. 9C, portions of the conductive liner 135 and the insulating liner 133 (for example, the portions of the conductive liner 135 and the insulating liner 133 formed on the shallow isolation patterns 140 and the first surface 110a of the semiconductor substrate 110) may be removed. Since the portions of the conductive liner 135 and the insulating liner 133 are removed, the upper surface of the shallow isolation patterns 140 and the first surface 110a of the semiconductor substrate 110 may be exposed.

In an embodiment, the portions of the conductive liner 135 and the insulating liner 133 may be removed using an ashing process. However, the method of removing the portions of the conductive liner 135 and the insulating liner 133 should not be limited thereto or thereby, and other known suitable removal methods may be employed.

Referring to FIG. 9D, the buried insulating pattern 131 may be formed in the second trench T2 in which the insulating liner 133 and the conductive liner 135 are formed. The buried insulating pattern 131 may cover the upper surface of the shallow isolation patterns 140 and the first surface 110a of the semiconductor substrate 110. The buried insulating pattern 131 may be formed using various processes, such as an atomic layer deposition process, a liquid-phase chemical vapor deposition, or a physical vapor deposition process.

The buried insulating pattern 131 may include a material that is non-conductive and has excellent gap-filling properties. As an example, the buried insulating pattern 131 may be formed of an oxide layer, such as silicon oxide, or may be formed of silicon nitride and/or silicon oxynitride. However, the material of the buried insulating pattern 131 should not be limited thereto or thereby.

Referring to FIG. 9E, the portion of the buried insulating pattern 131 (for example, the portion of the buried insulating pattern 131 that covers the upper surface of the shallow isolation patterns 140 and the first surface 110a of the semiconductor substrate 110) may be removed. The portion of the buried insulating pattern 131 may be removed through a chemical mechanical polishing (CMP) process, an etching process, or a combination of a chemical mechanical polishing (CMP) and an etching processes. As the etching process is performed, the semiconductor substrate 110 and/or some of the components in the semiconductor substrate 110 may further be removed. As an example, during the process of removing the portion of the buried insulating pattern 131, the upper portion of the shallow isolation pattern 140 and/or the upper portion of the first surface 110a of the semiconductor substrate 110 may be partially removed.

In this case, the chemical mechanical polishing (CMP) or etching process may be performed until the shallow isolation patterns 140 and the first surface 110a of the semiconductor substrate 110 are exposed to the outside. As a result, the upper surface of the shallow isolation patterns 140, the upper surface of the insulating liner 133, and the upper surface of the buried insulating pattern 131 may be exposed. In addition, the upper surfaces of the shallow isolation patterns 140, the upper surface of the insulating liner 133, and the upper surface of the buried insulating pattern 131 may form a coplanar surface (e.g., may be substantially coplanar to each other). In an embodiment, as the etching process is performed, the upper surface of the shallow isolation patterns 140, the upper surface of the insulating liner 133, and the upper surface of the buried insulating pattern 131 may be etched to different extents, and in this case, at least one of the upper surface of the shallow isolation patterns 140, the upper surface of the insulating liner 133, and the upper surface of the buried insulating pattern 131 may not be coplanar to each other.

Referring to FIG. 9F, the photodiode element 101 may be formed in the semiconductor substrate 110. For example, implanting the second conductive type dopant may be performed into the semiconductor substrate 110 to form the photodiode element 101. The second conductive type dopant may be an N-type dopant (which is different from the first conductive type dopant, such as a P-type dopant).

In addition, a source/drain region S/D may be formed in (as part of) the semiconductor substrate 110 such that impurities (charge carrier dopants) may be introduced into the substrate 110. The substrate 110 may not be materially distinctive from the source/drain region S/D.

The circuit wiring layer may be formed on the first surface 110a of the semiconductor substrate 110. As an example, the circuit wiring layer may include the gate pattern GP and the gate insulating layer GI, and the gate pattern GP and the gate insulating layer GI may be formed on the first surface 110a. In addition, the interlayer insulating layer 210, the contact via 230, and the conductive lines 220 may be formed on the first surface 110a.

Referring to FIG. 9G, the semiconductor substrate 110 may be inverted (or turned over) such that the second surface 110b faces upward. A thinning process may be performed on the second surface 110b of the inverted semiconductor substrate 110. As a result of the thinning process, a portion of the second surface 110b of the semiconductor substrate 110 may be removed. The portion of the second surface 110b of the semiconductor substrate 110 may be removed through the chemical mechanical polishing (CMP) process, the etching process, or a combination of a chemical mechanical polishing (CMP) and etching processes. The chemical mechanical polishing (CMP) process and/or the etching process may be performed until the insulating liner 133 of the PD isolation pattern 130 is exposed. Through the chemical mechanical polishing (CMP) process and/or the etching process, the upper surface of the insulating liner 133 and the second surface 110b of the semiconductor substrate 110 may form a coplanar surface.

In an embodiment of the present disclosure, the chemical mechanical polishing (CMP) process and/or the etching process may be modified in various ways, and, for example, may be performed until the buried insulating pattern 131 of the PD isolation pattern 130 is exposed. Alternatively, the chemical mechanical polishing (CMP) process and/or the etching process may be performed only as long as a portion of the semiconductor substrate 110 is removed while the PD isolation pattern remains unexposed.

The light control layer 310 may be formed on the second surface 110b of the semiconductor substrate 110 in which the portion of the PD isolation pattern 130 is exposed. The light control layer 310 may include an anti-reflective layer.

Referring to FIG. 9H, the color filters CF, the grid 320, the insulating layer 330, the microlenses (ML), and the contact portion CNT may be formed on the semiconductor substrate 110 on which the light control layer 310 is formed.

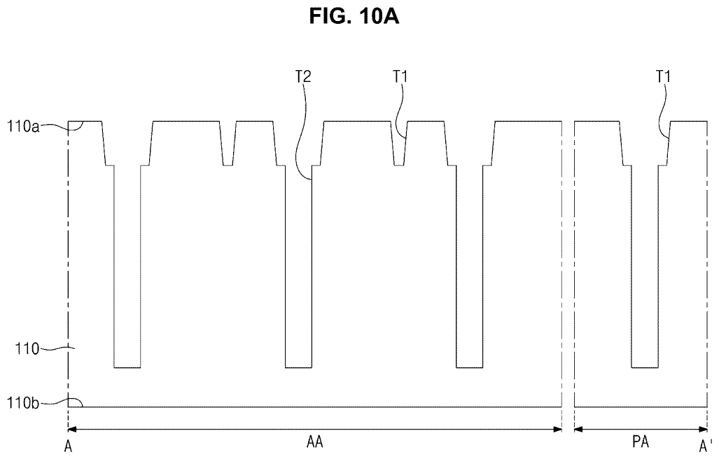

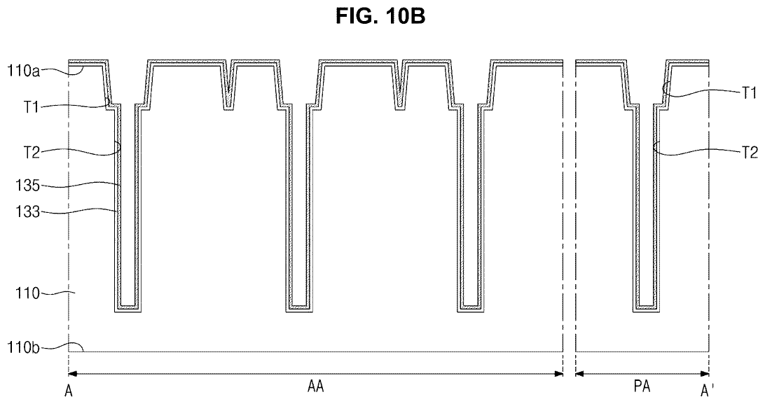

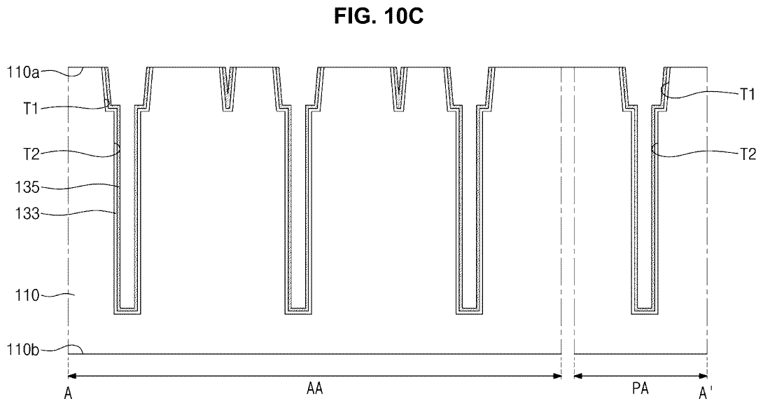

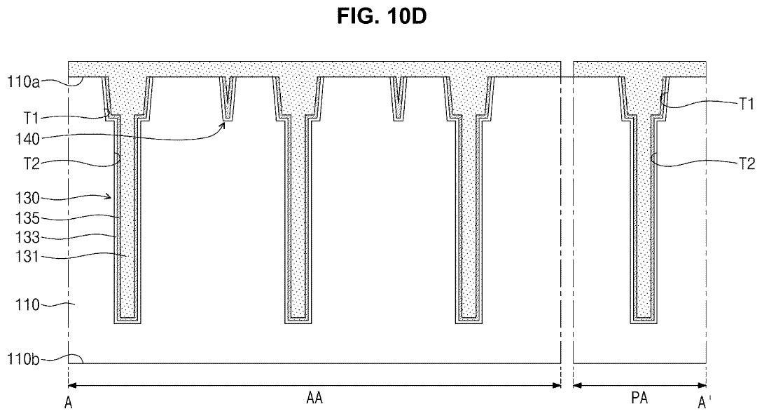

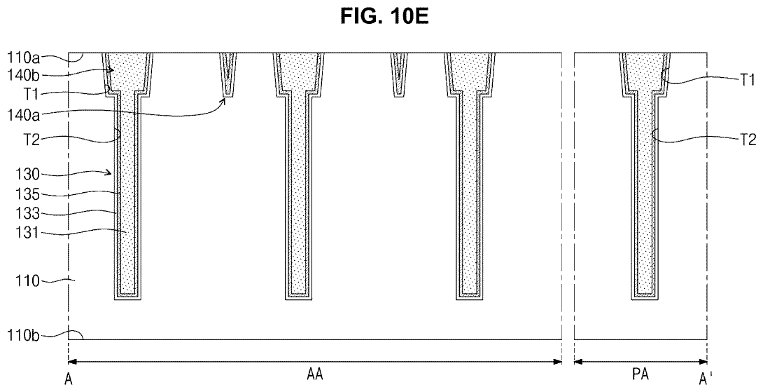

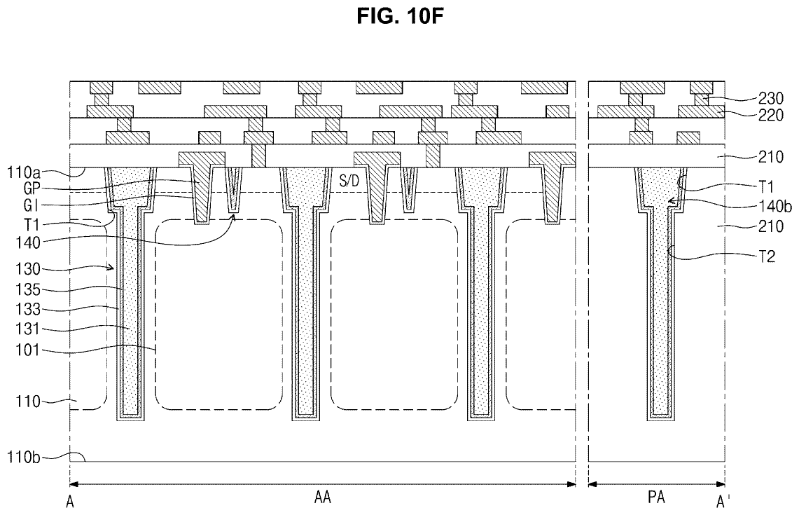

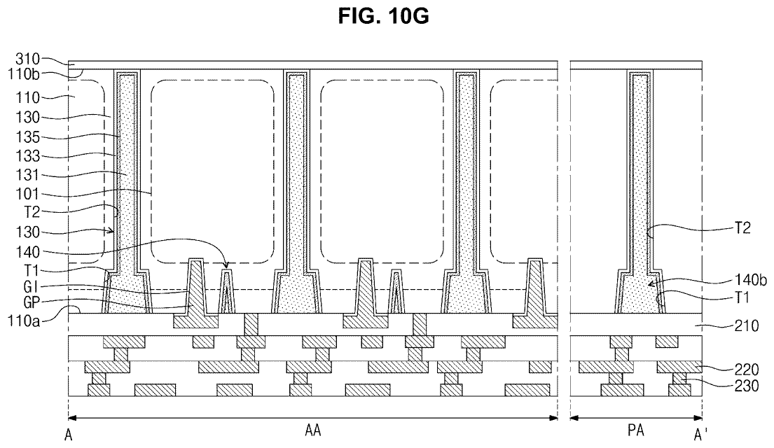

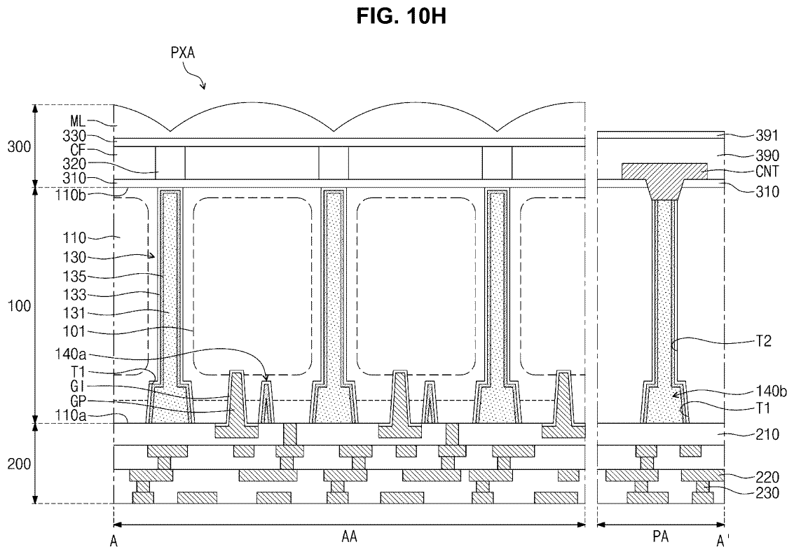

FIGS. 10A to 10H are cross-sectional views sequentially illustrating a method of manufacturing the image sensor according to an embodiment of the present disclosure. FIGS. 10A to 10H are cross-sectional views sequentially illustrating the manufacturing process of the image sensor according to an embodiment of the present disclosure and corresponding to FIG. 5.

Referring to FIG. 10A, the first trenches (or openings) T1 and the second trenches (or second opening) T2 may be formed in the semiconductor substrate 110. The first trenches T1 may be formed to be recessed from the first surface 110a of the semiconductor substrate 110 by a predetermined depth. The second trenches (or second trench) T2 may be formed to a greater depth (in a vertical direction) than the first trench T1. The first trenches T1 may be formed in the areas where the shallow isolation patterns 140 are to be provided, and the second trenches T2 may be formed in the area where the PD isolation pattern 130 is to be provided.

The first trenches T1 may be formed in both the area where the first shallow isolation pattern 140a is to be provided and the area where the second shallow isolation pattern 140b is to be provided. The second trenches T2 may be formed corresponding to the area where the PD isolation pattern 130 is to be provided and may be formed in the area in which the second shallow isolation patterns 140b are formed.

Some of the first trenches T1 together with the second trenches T2 may provide an interconnected space at the edge of the photodiode regions. For example, some of the first trenches T1 may be provided integrally with the second trenches T2 such that each of the second shallow isolation portions 140b may be formed in contact with (or integrally with) the PD isolation pattern 130 in a later process step.

Referring to FIG. 10B, the insulating liner 133 may be formed on the semiconductor substrate 110 in which the first trenches T1 and the second trenches T2 are formed. The insulating liner 133 may conformally cover inner walls of the first trenches T1 and the second trenches T2 as well as the upper surface of the semiconductor substrate 110.

The insulating liner 133 may be formed by using substantially the same manner as that described with reference to FIGS. 9A to 9H. For example, the insulating liner 133 may include the stable insulating material in which dangling bonds are absent or minimized or significantly reduced. For instance, the insulating liner 133 may include boron nitride. In an embodiment, the insulating liner 133 may be formed by a chemical vapor deposition (CVD) process, however, the method of forming the insulating liner 133 should not be limited thereto or thereby.

The conductive liner 135 may be formed on the semiconductor substrate 110 on which the insulating liner 133 is formed. The conductive liner 135 may conformally cover an inner wall of the insulating liner 133 in the first trenches T1 and the second trenches (or second trench) T2 as well as the upper surface of the semiconductor substrate 110.

The conductive liner 135 may be formed of a conductive material. In an embodiment, the conductive liner 135 may be formed by using substantially the same manner as that described with reference to FIGS. 9A to 9H. For example, the conductive liner 135 may include the conductive material having the two-dimensional network structure. Graphene may be used as the conductive material having the two-dimensional network structure.

In an embodiment, the conductive liner 135 may be formed by a chemical vapor deposition (CVD) process. However, the method of forming the conductive liner 135 should not be limited thereto or thereby.

In an embodiment, the conductive liner 135 may include the semiconductor material doped with the first conductive type dopant or the second conductive type dopant, for example, polycrystalline silicon doped with boron or phosphorus. When the conductive liner 135 includes polycrystalline silicon, the conductive liner 135 may be formed by an atomic layer deposition (ALD). When using the atomic layer deposition (ALD), the conductive liner 135 may be formed to a relatively thin thickness compared to other processes.

However, the method of forming the conductive liner 135 should not be limited thereto or thereby, and other methods may be employed as long as the conductive liner 135 is formed to a sufficiently thin thickness on the insulating liner 133.

Referring to FIG. 10C, a portion of the conductive liner 135 and a portion of the insulating liner 133 (for example, the portions of the conductive liner 135 and the insulating liner 133 formed on the first surface 110a of the semiconductor substrate 110) may be removed. Since the portion of the conductive liner 135 and the portion of the insulating liner 133 are removed, the first surface 110a of the semiconductor substrate 110 may be exposed.

In an embodiment, the portion of the conductive liner 135 and the portion of the insulating liner 133 may be removed using an ashing process. However, the method of removing the portion of the conductive liner 135 and the portion of the insulating liner 133 should not be limited thereto or thereby, and other known suitable removal methods may be employed.

Referring to FIG. 10D, the buried insulating pattern 131 may be formed in the first trenches T1 and the second trenches T2 in which the insulating liner 133 and the conductive liner 135 are formed. The buried insulating pattern 131 may also cover the first surface 110a of the semiconductor substrate 110. The buried insulating pattern 131 may be formed using various processes, such as an atomic layer deposition process, a liquid-phase chemical vapor deposition process, or a physical vapor deposition process.

The buried insulating pattern 131 may include a material that is non-conductive and has excellent gap-filling properties. As an example, the buried insulating pattern 131 may be formed of an oxide layer, such as silicon oxide, or may be formed of silicon nitride and/or silicon oxynitride. However, the material of the buried insulating pattern 131 should not be limited thereto or thereby.

Referring to FIG. 10E, the portion of the buried insulating pattern 131 (for example, the portion of the buried insulating pattern 131 that covers the upper surface of the shallow isolation patterns 140 and the first surface 110a of the semiconductor substrate 110) may be removed. The portion of the buried insulating pattern 131 may be removed through a chemical mechanical polishing (CMP) process, an etching process, or a combination of a chemical mechanical polishing (CMP) and etching processes. As the etching process is performed, the semiconductor substrate 110 and/or some of the components on the semiconductor substrate 110 may further be removed. For instance, during the process of removing the portion of the buried insulating pattern 131, the upper portion of the shallow isolation pattern 140 and the upper portion of the first surface 110a of the semiconductor substrate 110 may be partially removed.

In this case, the chemical mechanical polishing (CMP) or etching process may be performed until the upper surface of the shallow isolation patterns 140 and the first surface 110a of the semiconductor substrate 110 are exposed to the outside. As a result, the upper surface of the shallow isolation patterns 140, the upper surface of the insulating liner 133, and the upper surface of the buried insulating pattern 131 may be exposed to the outside. In addition, the upper surface of the shallow isolation patterns 140, the upper surface of the insulating liner 133, and the upper surface of the buried insulating pattern 131 may form a coplanar surface. In an embodiment, as the etching process is performed, the upper surface of the shallow isolation patterns 140, the upper surface of the insulating liner 133, and the upper surface of the buried insulating pattern 131 may be etched to different extents, and in this case, the upper surface of the shallow isolation patterns 140, the upper surface of the insulating liner 133, and the upper surface of the buried insulating pattern 131 may not form the coplanar surface.

Referring to FIG. 10F, the photodiode element 101 may be formed in the semiconductor substrate 110. For example, implanting the second conductive type dopant may be performed into the semiconductor substrate 110 to form the photodiode element 101. The second conductive type dopant may be an N-type dopant (which is different from the first conductive type dopant, such as a P-type dopant).

In addition, a source/drain region S/D may be formed in (as part of) the semiconductor substrate 110 such that impurities (charge carrier dopants) may be introduced into the substrate 110. The substrate 110 may not be materially distinctive from the source/drain region S/D.

The circuit wiring layer may be formed on the first surface 110a of the semiconductor substrate 110. As an example, the circuit wiring layer may include the gate pattern GP and the gate insulating layer GI, and the gate pattern GP and the gate insulating layer GI may be formed on the first surface 110a. In addition, the interlayer insulating layer 210, the contact vias 230, and the conductive lines 220 may be formed on the first surface 110a.

Referring to FIG. 10G, the semiconductor substrate 110 may be inverted such that the second surface 110b faces upward. A thinning process may be performed on the second surface 110b of the inverted semiconductor substrate 110. As a result of the thinning process, a portion of the second surface 110b of the semiconductor substrate 110 may be removed.

A portion of the semiconductor substrate 110 may be removed by the chemical mechanical polishing (CMP) process, the etching process, or a combination of a chemical mechanical polishing (CMP) and etching processes. The second surface 110b of the semiconductor substrate 110 may be subjected to the removing process. The chemical mechanical polishing (CMP) process and/or the etching process may be performed until the insulating liner 133 of the PD isolation pattern 130 is exposed. Through the chemical mechanical polishing (CMP) process and/or the etching process, the upper surface of the insulating liner 133 and the second surface 110b of the semiconductor substrate 110 may form a coplanar surface.

In an embodiment of the present disclosure, the chemical mechanical polishing (CMP) process and/or the etching process may be modified in various ways, and, for example, may be performed until the buried insulating pattern 131 of the PD isolation pattern 130 is exposed. Alternatively, the chemical mechanical polishing (CMP) process and/or the etching process may be performed only as long as a portion of the semiconductor substrate 110 is removed while a PD isolation pattern remains unexposed.

The light control layer 310 may be formed on the second surface 110b of the semiconductor substrate 110 on which the portion of the PD isolation pattern 130 is exposed. The light control layer 310 may include an anti-reflective layer.

Referring to FIG. 10H, the color filters CF, the grid 320, the insulating layer 330, the microlenses ML, and the contact portion CNT may be formed on the semiconductor substrate 110 on which the light control layer 310 is formed.

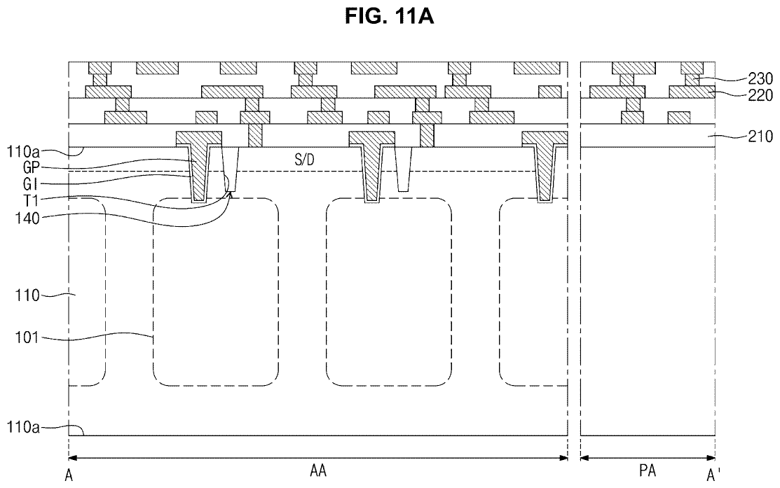

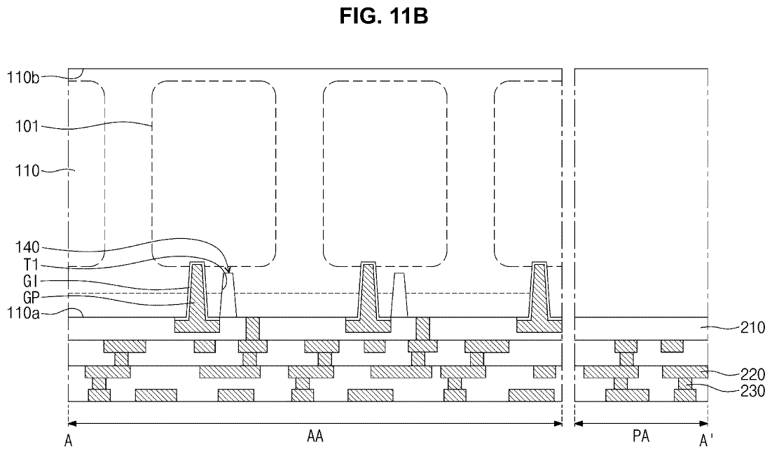

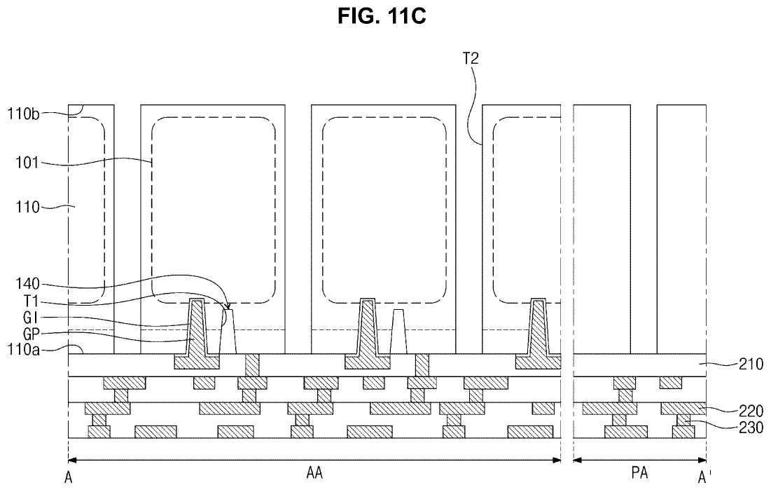

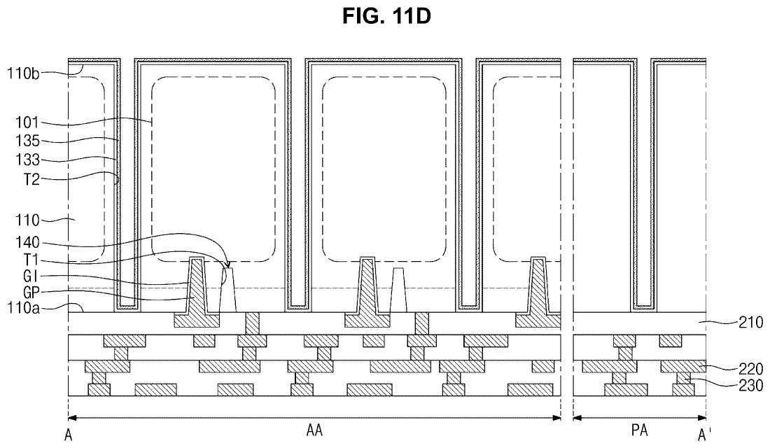

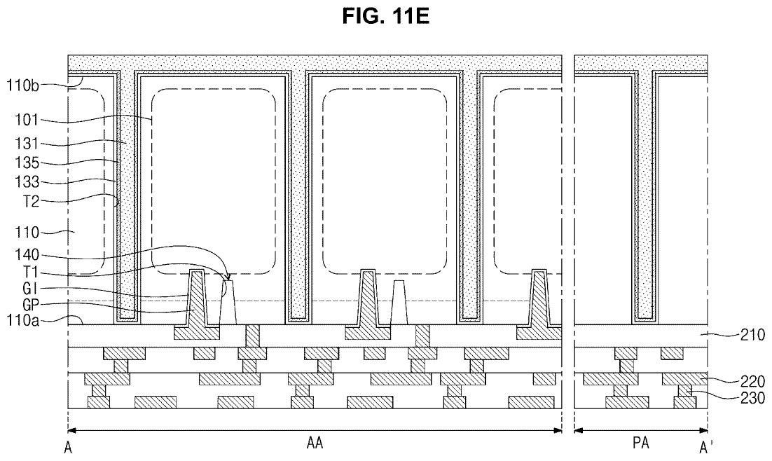

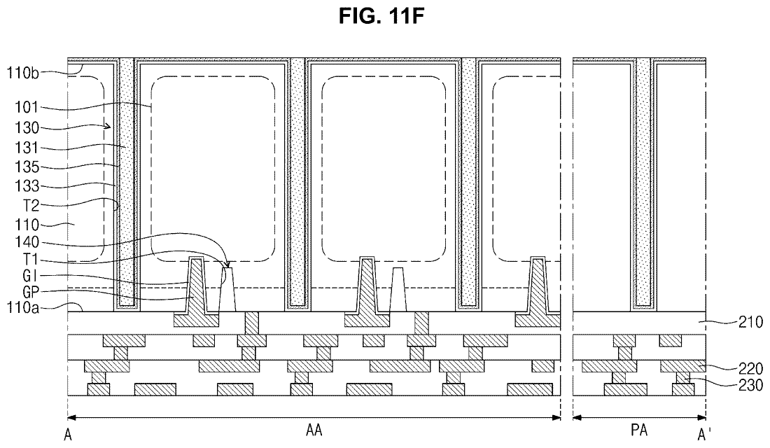

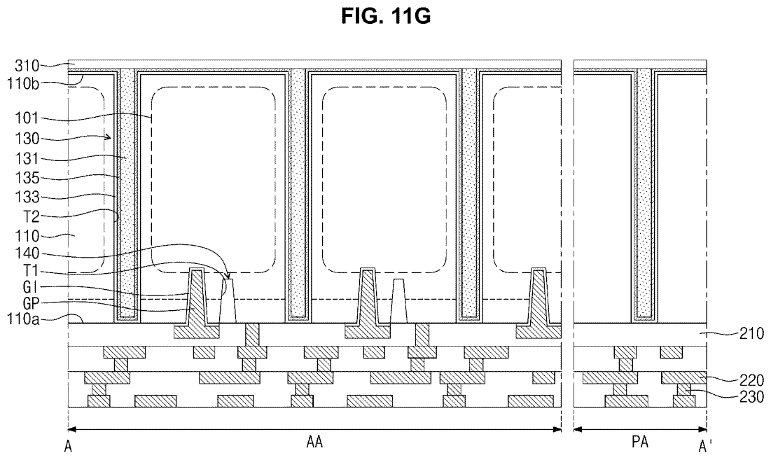

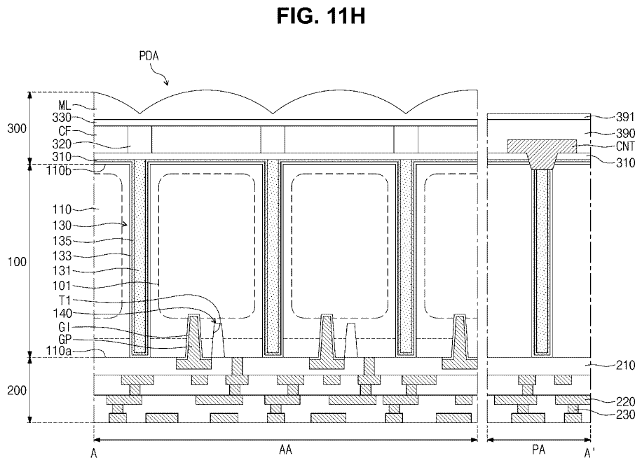

FIGS. 11A to 11H are cross-sectional views sequentially illustrating a method of manufacturing the image sensor according to an embodiment of the present disclosure. FIGS. 11A to 11H are cross-sectional views sequentially illustrating the manufacturing process of the image sensor according to an embodiment of the present disclosure and corresponding to FIG. 6.

Referring to FIG. 11A, the semiconductor substrate 110 including the first surface 110a and the second surface 110b facing away from the first surface 110a may be provided.

The shallow isolation patterns 140 may be formed on the semiconductor substrate 110. The shallow isolation patterns 140 may be formed adjacent to the first surface 110a and may be buried in (e.g., formed on and recessed into) the semiconductor substrate 110. The shallow isolation patterns 140 may be formed by forming the first trench T1 recessed from the first surface 110a of the semiconductor substrate 110 and then filling the first trench T1. The shallow isolation patterns 140 may be formed of an insulating material and may include a silicon oxide layer, a silicon nitride layer, and/or a silicon oxynitride layer. The shallow isolation patterns 140 may not be disposed at an edge of the photodiode regions. For example, the shallow isolation patterns 140 may not be disposed in an area overlapping the PD isolation pattern 130 or adjacent to the PD isolation pattern 130 in a cross sectional view.

The photodiode element 101 may be formed in the semiconductor substrate 110. For example, implanting the second conductive type dopant may be performed into the semiconductor substrate 110 to form the photodiode element 101. The second conductive type dopant may be an N-type dopant (which is different from the first conductive type dopant, such as a P-type dopant).

The circuit wiring layer may be formed on the first surface 110a of the semiconductor substrate 110. In addition, the interlayer insulating layer 210, the contact via 230, and the conductive lines 220 may be formed on the first surface 110a.

In an embodiment, an additional structure may further be formed under (or on) the circuit wiring layer. As an example, the second structure S2, as shown in FIG. 7, may further be formed under (or on) the circuit wiring layer. Alternatively, the second structure S2 and the third structure S3, as shown in FIG. 8, may further be formed under (or on) the circuit wiring layer. In the following embodiment, for convenience of explanation, only the structure corresponding to the first structure S1 will be described without explaining the additional formation of the second structure S2 and/or the third structure S3.

Referring to FIG. 11B, the semiconductor substrate 110 may be inverted (or turned over) such that the second surface 110b faces upward. A thinning process may be performed on the second surface 110b of the inverted semiconductor substrate 110. As a result of the thinning process, a portion of the second surface 110b of the semiconductor substrate 110 may be removed.

A portion of the semiconductor substrate 110 may be removed by a chemical mechanical polishing (CMP) process, an etching process, or a combination of a chemical mechanical polishing (CMP) and etching processes. The second surface 110b of the semiconductor substrate 110 may be subjected to the removing process.

Referring to FIG. 11C, the second trenches (or second trench) T2 may be formed in the semiconductor substrate 110. In an embodiment, the second trenches T2 may extend from the second surface 110b of the semiconductor substrate 110 to the first surface 110a of the semiconductor substrate 110. The second trenches T2 may be formed by forming a mask pattern that defines an area in which the PD isolation pattern 130 is to be formed and etching the semiconductor substrate 110 using the mask pattern.

The second trenches T2 may penetrate through both the first surface 110a and the second surface 110b of the semiconductor substrate 110. As an example, the second trenches T2 may completely penetrate through the semiconductor substrate 110, and thus, an upper surface of the uppermost layer among the interlayer insulating layers 210 may be exposed. For example, the lower surface of the second trenches (or second trench) T2 may correspond to the upper surface of the uppermost layer among the interlayer insulating layers 210.

In an embodiment, although not shown in figures, the second trenches T2 may not completely penetrate through the semiconductor substrate 110. In this case, the lower surface of the second trenches T2 may be spaced apart from the first surface 110a of the semiconductor substrate 110.

Referring to FIG. 11D, the insulating liner 133 may be formed on the semiconductor substrate 110 in which the second trenches T2 is formed. The insulating liner 133 may cover an inner wall of the second trenches T2 and may conformally cover the upper surface of the semiconductor substrate 110 in which the shallow isolation patterns 140 are formed.

The insulating liner 133 may be formed by using substantially the same manner as that described with reference to FIGS. 9A to 9H. For example, the insulating liner 133 may include the stable insulating material in which dangling bonds are absent or minimized or significantly reduced. For instance, the insulating liner 133 may include boron nitride. In an embodiment, the insulating liner 133 may be formed by a chemical vapor deposition (CVD) process, however, the method of forming the insulating liner 133 should not be limited thereto or thereby.

The conductive liner 135 may be formed on the semiconductor substrate 110 on which the insulating liner 133 is formed. The conductive liner 135 may conformally cover an inner wall of the insulating liner 133 in the second trenches (or second trench) T2 as well as the upper surface of the semiconductor substrate 110.

The conductive liner 135 may be formed of a conductive material. In an embodiment, the conductive liner 135 may be formed by using substantially the same manner as that described with reference to FIGS. 9A to 9H. For example, the conductive liner 135 may include the conductive material having the two-dimensional network structure. Graphene may be used as the conductive material having the two-dimensional network structure.

In an embodiment, the conductive liner 135 may be formed by a chemical vapor deposition (CVD) process. However, the method of forming the conductive liner 135 should not be limited thereto or thereby.

In an embodiment, the conductive liner 135 may include the semiconductor material doped with the first conductive type dopant or the second conductive type dopant, for example, polycrystalline silicon doped with boron or phosphorus. When the conductive liner 135 includes polycrystalline silicon, the conductive liner 135 may be formed by an atomic layer deposition (ALD). When using the atomic layer deposition (ALD), the conductive liner 135 may be formed to a relatively thin thickness compared to other processes.

However, the method of forming the conductive liner 135 should not be limited thereto or thereby, and other methods may be employed as long as the conductive liner 135 is formed to a sufficiently thin thickness on the insulating liner 133.

Referring to FIG. 11E, the buried insulating pattern 131 may be formed in the second trenches T2 in which the insulating liner 133 and the conductive liner 135 are formed. The buried insulating pattern 131 may cover the upper surface of the conductive liner 135. The buried insulating pattern 131 may be formed using various processes, such as an atomic layer deposition process, a liquid-phase chemical vapor deposition process, or a physical vapor deposition process.

The buried insulating pattern 131 may include a material that is non-conductive and has excellent gap-filling properties. As an example, the buried insulating pattern 131 may be formed of an oxide layer, such as silicon oxide, or may be formed of silicon nitride and/or silicon oxynitride. However, the material of the buried insulating pattern 131 should not be limited thereto or thereby.

Referring to FIG. 11F, the portion of the buried insulating pattern 131 (for example, the buried insulating pattern 131 disposed on the upper surface of the conductive liner 135) may be removed. The portion of the buried insulating pattern 131 may be removed through a chemical mechanical polishing (CMP) process, an etching process, or a combination of a chemical mechanical polishing (CMP) and etching processes.

In this case, the chemical mechanical polishing (CMP) or etching process may be performed until the upper surface of the conductive liner 135 is exposed to the outside. As a result, the upper surface of the conductive liner 135 may be exposed to the outside, and the upper surface of the conductive liner 135 and the upper surface of the buried insulating pattern 131 may form a coplanar surface. In an embodiment, as the etching process is performed, the upper surface of the conductive liner 135 and the upper surface of the buried insulating pattern 131 may be etched to different extents, and in this case, the upper surface of the conductive liner 135 and the upper surface of the buried insulating pattern 131 may not form the coplanar surface.

Referring to FIG. 11G, the light control layer 310 may be formed on the second surface 110b of the semiconductor substrate 110 through which the upper surfaces of the buried insulating pattern 131 and the conductive liner 135 are exposed. The light control layer 310 may include an anti-reflective layer. In an embodiment, the light control layer may not include a fixed charge layer.

Referring to FIG. 11H, the color filters CF, the grid 320, the insulating layer 330, the microlenses ML, and the contact portion CNT may be formed on the semiconductor substrate 110 on which the light control layer 310 is formed.

Although the embodiments of the present disclosure have been described, it is understood that the present invention should not be limited to these embodiments but various changes and modifications can be made by one ordinary skilled in the art within the spirit and scope of the present invention. The implementations of the above-described embodiments of the present disclosure may also be applied to other processes and/or other devices having at least some different configurations from the aforementioned embodiments.

Therefore, the invention should not be limited to any single embodiment described herein.

What is claimed is:

1. An image sensor comprising:
a semiconductor substrate comprising a first surface and a second surface opposite to the first surface;
photodiodes defined in the semiconductor substrate;
a photodiode (PD) isolation pattern disposed in a trench penetrating through at least one of the first surface and the second surface of the semiconductor substrate; and
microlenses disposed on the second surface,
wherein the PD isolation pattern comprises:
an insulating pattern disposed within the semiconductor substrate,
a first insulating liner disposed between the insulating pattern and the semiconductor substrate, and
a first conductive liner disposed between the first insulating liner and the insulating pattern, and
wherein one of the first insulating liner and the first conductive liner comprises a two-dimensional material.

2. The image sensor of claim 1, wherein the first insulating liner comprises a two-dimensional material of hexagonal boron nitride (h-BN).

3. The image sensor of claim 1, wherein the first conductive liner comprises graphene.

4. The image sensor of claim 1, wherein the first conductive liner comprises polycrystalline silicon doped with a dopant.

5. The image sensor of claim 1, wherein:
the PD isolation pattern extends, in a direction, from the first surface toward the second surface.

6. The image sensor of claim 1, wherein the PD isolation pattern extends, in a direction, from the second surface toward the first surface.

7. The image sensor of claim 6, wherein the first insulating liner and the first conductive liner extend onto the second surface to cover the second surface.

8. The image sensor of claim 1, further comprising shallow isolation patterns disposed in multiple shallow trenches in cross sectional views, each of the shallow isolation patterns having a depth in a vertical direction smaller than the PD isolation pattern.

9. The image sensor of claim 8, wherein:
the PD isolation pattern defines a plurality of photodiode regions,
the photodiodes are formed in the plurality of photodiode regions, and
each of the shallow isolation patterns comprises:
a first shallow isolation portion disposed in a corresponding one of the plurality of photodiode regions in a cross sectional view, and
a second shallow isolation portion disposed at an edge of the corresponding one of the plurality of photodiode regions in the cross sectional view.

10. The image sensor of claim 9, when the shallow trenches are referred to as first trenches and the trench is referred to as a second trench, and some of the first trenches together with the second trench provide an interconnected space.

11. The image sensor of claim 9, wherein each of the second shallow isolation portions is provided integrally with the PD isolation pattern without being separated from the PD isolation pattern.

12. The image sensor of claim 9,
wherein each of the first shallow isolation portions and/or each of the second shallow isolation portions comprises a second conductive liner and a second insulating liner, and
wherein the second conductive liners are formed integrally with the first conductive liner, and/or the second insulating liners are formed integrally with the first insulating liner.

13. The image sensor of claim 1, further comprising a contact pattern connected to the first conductive liner,
wherein the semiconductor substrate comprises an active area and a peripheral area located adjacent to the active area,
wherein the photodiodes are disposed in the active area, and
wherein the contact pattern is disposed on the peripheral area.

14. The image sensor of claim 13, wherein the contact pattern is disposed on the second surface or a position adjacent to the second surface.

15. The image sensor of claim 14, wherein the first conductive liner is configured to be electrically connected to a negative bias voltage through the contact pattern.

16. The image sensor of claim 1, further comprising a light control layer disposed between the second surface of the semiconductor substrate and the microlenses.

17. The image sensor of claim 16, wherein the light control layer is an anti-reflective layer.

18. An image sensor comprising:
a semiconductor substrate; and
a PD isolation pattern disposed in an opening penetrating at least a portion of the semiconductor substrate,
wherein the PD isolation pattern comprises:
an insulating liner covering a sidewall of the opening, and
a conductive liner covering a side surface of the insulating liner,
wherein one of the insulating liner and the conductive liner comprises a material having a two-dimensional material.

19. An image sensor comprising:
a first substrate comprising a first surface and a second surface opposite to the first surface;
a photodiode defined in the first substrate;
a PD isolation pattern disposed in an opening penetrating through at least one of the first surface and the second surface of the first substrate;
a microlens disposed on the second surface;
a first bonding pad disposed on the first surface;
a second substrate, wherein the first substrate is stacked on the second substrate;
a peripheral circuit provided with the second substrate; and
a second bonding pad connected to the first bonding pad,
wherein the PD isolation pattern comprises:
an insulating pattern disposed in the opening,
an insulating liner disposed between the insulating pattern and the first substrate, and
a conductive liner disposed between the insulating liner and the insulating pattern,
wherein one of the insulating liner and the conductive liner comprises a material having a two-dimensional material.

20. The image sensor of claim 19, wherein the insulating liner comprises a two-dimensional material of hexagonal boron nitride (h-BN), and the conductive liner comprises graphene.
